(19) United States
(12) Patent Application Publication
(10) Pub. No.: US 2022/0216482 A1
(43) Pub. Date: Jul. 7, 2022

(54) LITHIUM METAL ANODE ASSEMBLIES AND AN APPARATUS AND METHOD OF MAKING SAME

(71) Applicant: 2555663 Ontario Limited, Toronto, Ontario (CA)

(72) Inventors: Maciej Jastrzebski, Toronto, Ontario (CA); Timothy Johnston, Toronto, Ontario (CA)

(73) Assignee: 2555663 Ontario Limited, Toronto, Ontario (CA)

(21) Appl. No.: 17/604,009

(22) PCT Filed: Apr. 17, 2020
(86) PCT No.: PCT/CA2020/050513

§ 371 Date: Oct. 15, 2021

Related U.S. Application Data
(60) Provisional application No. 62/835,141, filed on Apr. 17, 2019.

(51) Int. Cl. H01M 4/66; H01M 4/134; H01M 4/1395; H01M 4/04; H01M 10/052

(52) U.S. Cl. CPC H01M 4/661; H01M 4/134; H01M 4/1395; H01M 4/667; H01M 2004/027; H01M 10/052; H01M 4/0409; H01M 4/0404; H01M 4/0423

(57) ABSTRACT

An anode assembly for use in a lithium-based battery may include a current collector comprising aluminum, at least a first protective layer bonded to and covering a portion of the collector and being formed from a protective metal that is electrically conductive, and at least a first reactive layer comprising lithium metal bonded to the protective. The first protective layer can be disposed between the support surface and the reactive layer so that electrons can travel from the first reactive layer to the current collector and the first reactive layer is spaced from and at least substantially ionically isolated from the support surface, and whereby diffusion of the reactive layer to the current collector is substantially prevented, by the first protective layer thereby inhibiting reactions between the lithium metal and the current collector.

### CROSS REFERENCE TO RELATED APPLICATION

This application claims the benefit of and priority to U.S. Provisional Application No. 62/835,141 filed Apr. 17, 2019 and entitled Low-Cost Lithium Metal Anode Assembly, the entirety of which is incorporate herein by reference.

### FIELD OF THE INVENTION

In one of its aspects, the present disclosure relates to the production and use of anode assemblies that are suitable for use with lithium ion and lithium metal solid state batteries, and methods and apparatuses for producing the same.

### INTRODUCTION

Japanese patent publication no. JP2797390B2 discloses a negative electrode and a carbonaceous material and a current collector as an anode active material, a positive electrode having a lithium compound as a positive electrode active material, a secondary battery and a nonaqueous electrolyte, the positive electrode active material, the second having a main active material composed of a first lithium compound having a nobler potential than the oxidation potential of the current collector, a lower potential than the oxidation potential of the collector. By including a subsidiary active substance consisting of lithium compound, it is obtained so as to have excellent properties against over-discharge.

U.S. Pat. No. 10,177,366 discloses a high purity lithium and associated products. In a general embodiment, the present disclosure provides a lithium metal product in which the lithium metal is obtained using a selective lithium ion conducting layer. The selective lithium ion conducting layer includes an active metal ion conducting glass or glass ceramic that conducts only lithium ions. The present lithium metal products produced using a selective lithium ion conducting layer advantageously provide for improved lithium purity when compared to commercial lithium metal. Pursuant to the present disclosure, lithium metal having a purity of at least 99.96 weight percent on a metals basis can be obtained.

U.S. Pat. No. 7,390,591 discloses ionically conductive membranes for protection of active metal anodes and methods for their fabrication. The membranes may be incorporated in active metal negative electrode (anode) structures and battery cells. In accordance with the invention, the membrane has the desired properties of high overall ionic conductivity and chemical stability towards the anode, the cathode and ambient conditions encountered in battery manufacturing. The membrane is capable of protecting an active metal anode from deleterious reaction with other battery components or ambient conditions while providing a high level of ionic conductivity to facilitate manufacture and/or enhance performance of a battery cell in which the membrane is incorporated.

### SUMMARY

Attempts have been previously made to provide lithium anodes suitable for solid-state batteries (SSB). One way of eliminating some of the difficulties of handling lithium anodes is to form the anode in place on a stronger substrate. This allows loads to pass through a stronger material which, in some cases, can also function as the anode current collector.

For example, U.S. Pat. No. 10,177,366 teaches a lithium anode deposited on a substrate, made by electrolysis from an aqueous solution of lithium chemicals through a lithium ion-selective membrane. This approach applies a lithium coating to one of a number of substrates. The process requires a strip coating machine and uses a relatively small area of membrane to achieve the coating. The process suffers from several drawbacks for battery manufacture, which make it unlikely to be unattractive for SSB lithium anode production:
Electrodeposition rates are low, therefore high-volume production requires a large capital investment, resulting in a high all-in cost of production.
The process uses flammable organic electrolytes, which, combined with the tendency of electrolysis systems to spark, creates a fire hazard.
It may be impractical to make large, durable solid electrolytes or ion-selective membranes, which means the production rate from such a machine may not be high, therefore it is unlikely that an economically attractive cost can be achieved.

U.S. Pat. No. 7,390,591 discloses a protected lithium anode formed on a lithium ion-conducting glass substrate by various processes, including physical vapor deposition. The ion-conductive glass is intended to function as a separator and part of a layered solid electrolyte. This process is suitable for manufacturing lithium SSBs with a glass separator, and overcomes the problem associated with lithium reactivity by protecting it from attack by atmospheric gases. However, the disclosed anode has several drawbacks:
It requires a current collector made of copper which is intrinsically expensive and imposes a significant floor cost (see Table 7 for comparison of substrate material costs).
It is suitable for batteries using a glass separator but may not be suitable for other battery designs.

U.S. Pat. No. 5,522,955 discloses a lithium anode and production equipment based on a physical vapor deposition process. The proposed equipment deposits an 8-25 micron thick layer of lithium on copper, nickel, stainless steel, or a conductive polymer. Vapor deposition is an inexpensive process used to produce packaging materials at large scales, and so may be capable of making anodes at an attractive cost. However this disclosure further contemplates the application of an ion-conductive polymer to the anode surface to protect its surface from oxidation and nitridation when it is exposed to air, and to create a partial cell assembly. This second step is done in a separate chamber from that in which the vapor deposition is conducted. This may have some shortcomings, including:
It requires a current collector made of copper which is intrinsically expensive and imposes a significant floor cost (see Table 7 for comparison of substrate material costs).
The equipment required to apply the protective coating is complicated and requires a separate processing chamber.

While the prior art addresses some of the shortcomings of lithium foil anodes, to date, no effective process for producing low-cost SSB lithium anodes has been developed. The present disclosure aims to address this hurdle, which may be impeding the adoption of lithium SSBs, by providing helping to facilitate the manufacture and/or use of a relatively improved, low-cost lithium metal anode assembly, manufacturing process, and equipment for its production.

In accordance with one broad aspect of the teachings described herein a low-cost lithium anode assembly can include an aluminum foil current collector, with at least one side bonded to at least one layer of protective metal, bonded to at least one layer of lithium metal.

The protective metal layer may include at least one of, copper, gold, silver, nickel, or stainless steel.

The protective metal layer may be between 1-75000 Angstroms thick, more preferably 1-150 Angstroms thick, and most preferably 20-50 Angstroms thick.

The lithium metal layer is between 0.001-100 microns thick, but most preferably between 0.01-20 microns thick.

At least one of the layers may be formed by a vapour deposition process.

The battery may be a solid-state battery using a solid or semi-solid electrolyte.

The battery may be a lithium ion cell battery using a liquid or gel electrolyte.

The protective metal may be sealed at its perimeter, using a sealing method that may include one of physical vapour deposition, polymer film or polymer resin application, or crimping.

In accordance with another broad aspect of the teachings described herein, a process for producing low-cost lithium anode assemblies can include the steps of:
a. Loading at least one substrate roll into an air-lock chamber of a roll-to-roll physical vapor deposition machine;
b. Sealing the air-lock chamber from the atmosphere;
c. Evacuating the air-lock chamber of a roll-to-roll physical vapor deposition machine;
d. Transferring the roll to the metallizing chamber of a roll-to-roll physical vapor deposition machine equipped with at least one protective metal vapour source, and at least one reactive metal vapour source;
e. Roll-to-roll metallizing the roll of substrate with both the protective metal and the reactive metal;
f. Returning the roll to the air-lock chamber;
g. Repeating steps b to f zero or more times;
h. Re-pressurizing the air-lock chamber;
i. Unloading at least one metallized substrate roll from the air-lock chamber.

Steps a to i may be repeated zero or more times without re-pressurizing the metallizing chamber.

The re-pressurizing gas may be an inert gas, such as argon, helium, neon, xenon or krypton.

At least one metallized substrate roll may be placed in a hermetically sealed container prior to unloading from the air-lock chamber.

The substrate may include copper, aluminum, nickel, stainless steel, steel, a conductive polymer, and/or a polymer.

The protective metal may include copper, silver, gold, nickel, and/or stainless steel.

The reactive metal may include lithium, potassium, rubidium, cesium, calcium, magnesium, or aluminum.

In accordance with another broad aspect of the teachings described herein a roll-to-roll physical vapor deposition machine may include: at least one metallizing chamber; a vacuum pumping system; driven roll spindles; at least one metal evaporation source; at least one air-lock chamber; at least one roll transfer mechanism; at least one vacuum-tight door communicating between metallizing chamber and air-lock chamber; and at least one vacuum-tight door communicating between the air-lock chamber and the atmosphere. The spindles may be reversible.

The machine may also have at least one of: a roll magazine, a computer control system and an inert gas re-pressurization system.

According to another broad aspect of the teachings described herein, an anode assembly for use in a lithium-based battery, may include a current collector comprising aluminum and having a first side with a support surface. At least a first protective layer may be bonded to and covering the support surface. The protective layer may include a protective metal and may be electrically conductive. At least a first reactive layer including lithium metal may be bonded to the protective layer and may be configured to contact an electrolyte when the anode assembly is in use. The first protective layer may be disposed between the support surface and the reactive layer so that electrons can travel from the first reactive layer to the current collector and the first reactive layer is spaced from and at least substantially ionically isolated from the support surface, whereby diffusion of the reactive layer to the current collector may be substantially prevented, by the first protective layer thereby inhibiting reactions between the lithium metal and the current collector.

The current collector may include a continuous aluminum foil.

The aluminum foil may have a thickness of between about 1 and about 100 microns.

The aluminum foil may be configured as a continuous web that comprises the support surface and physically supports the first protective layer.

The protective metal may include at least one of copper, nickel, silver, stainless steel and steel.

The first protective layer may be deposited onto the support surface via physical vapour deposition and bonds to the support surface in the absence of a separate bonding material.

The first protective layer may have a thickness of between about 1 and about 75,000 Angstroms.

The first protective layer may have a thickness of between about 200 and about 7500 Angstroms.

The first protective layer may have an isolation thickness and may be shaped so that the first reactive layer is completely ionically isolated from the current collector.

The protective metal may be unreactive with the lithium metal.

The protective metal may cover the entire first side of the current collector.

The first reactive layer may have a thickness of between about 0.001 and about 100 microns.

The first reactive layer may have a thickness of between about 0.01 and about 20 microns.

The first reactive layer may be deposited onto the first protective layer via physical vapour deposition and bonds to the first protective layer.

The anode assembly may be free of lithium metal foil.

The current collector may include an opposing second side and further include a second protective layer bonded to and cover the second side and comprising the protective metal.

A perimeter of the first protective layer may be joined to a corresponding perimeter of the second protective layer thereby sealing the current collector with the protective metal.

The first protective layer may be joined to a corresponding perimeter of the second protective layer via at least one of physical vapour deposition, application of a polymer film, application of a polymer resin and mechanical crimping of the perimeters.

The assembly may include a second reactive layer comprising lithium metal bonded to the second protective layer and being configured to contact an electrolyte when the anode assembly is in use.

In accordance with another broad aspect of the teachings described herein, a method of manufacturing an anode assembly for use in an active metal-based battery, may include the steps of a) providing a current collector comprising metallic substrate and having a first side with a support surface within an interior of a metalizing chamber that is at an operating pressure that is less than about 10-2 Torr, b) covering the support surface with at least a first protective layer comprising a protective metal that is electrically conductive and that is deposited on the support surface via a first physical vapour deposition process; and c) covering the first protective layer with at least a first reactive layer comprising a reactive metal that is deposited on the first protective layer via a second physical vapour deposition process, the first reactive layer being configured to contact an electrolyte when the anode assembly is in use. The first protective layer may be disposed between the support surface and the reactive layer so that electrons can travel from the first reactive layer to the current collector and the first reactive layer is spaced from and at least substantially ionically isolated from the support surface, and whereby diffusion of the reactive layer to the support surface may be prevented by the first protective layer thereby inhibiting reactions between the reactive metal and the current collector.

The metallic substrate may be a foil having a thickness of between about 1 and about 100 microns and comprising at least one of copper, aluminium, nickel, stainless steel, steel, an electrically conductive polymer and a polymer.

The metallic substrate may include a continuous foil web that is unwound from a first input roll prior to step a) and wound onto a first output roll after step c).

Steps b) and c) may be carried out while the web is moving between the first input roll and the first output roll.

The web may be moving at a processing speed of between about 20 and about 1500 m/min.

Step b) may include providing the protective metal from at least one protective metal vapour source apparatus that is configured to deposit between about 0.001 and about 10 microns of the protective metal on the support surface in a single pass while the web is moving at the processing speed.

Step b) may include depositing the protective metal onto the support surface until the first protective layer has as thickness of between about 1 and about 75,000 Angstroms.

Step c) may include providing the reactive metal from at least one reactive metal vapour source apparatus that is spaced downstream from the at least one protective metal vapour source apparatus that is configured to deposit between about 0.001 and about 10 microns of the active metal on the first protective layer in a single pass while the web is moving at the processing speed.

Step c) may include depositing the active metal onto the first protective layer until first active layer has a thickness of between about 0.001 and about 100 microns.

The first input roll may be supported by an unwinding apparatus that is disposed within the metalizing chamber.

The first output roll may be supported by a winding apparatus that is disposed within the metalizing chamber at the operating pressure.

The may include, prior to step a): reducing the pressure in the interior of the metalizing chamber from generally atmospheric pressure to the operating pressure; and introducing the first input roll into the interior of the metalizing chamber via an airlock whereby the first input roll can be conveyed from outside the metalizing chamber to inside the metalizing chamber without increasing a pressure in the interior of the metalizing chamber above I kPa.

The method may include, after step c), removing the first output roll from the interior of the metalizing chamber via an airlock whereby the first output roll can be conveyed from inside the metalizing chamber to outside the metalizing without increasing a pressure within the interior of the metalizing chamber above I kPa.

The method may include sealing the first output roll within an air tight receiving chamber having an interior that is substantially free of oxygen prior to removing the first output roll from the airlock.

After depleting the first input roll the method may include introducing a second input roll into the interior of the metalizing chamber via an airlock and without increasing a pressure in the interior of the metalizing chamber above I kPa, and repeating steps a) to c) with a metallic substrate unwound from the second input roll.

The reactive metal may include at least one of lithium, potassium, rubidium, cesium, calcium, magnesium and aluminum.

The reactive metal may be lithium.

The interior of the metalizing chamber may be substantially free of oxygen during steps a)-c).

The method may include covering an opposing a second side of the current collector with a second protective layer comprising the protective metal via a third physical vapour deposition process.

The method may include sealing a perimeter of the first protective layer to a perimeter of the second protective layer to seal the current collector.

The method may include sealing the perimeter of the first protective layer to the perimeter of the second protective layer comprises mechanically crimping the perimeters together.

The method may include covering the second protective layer with a second reactive layer comprising the reactive metal via a fourth physical vapour deposition process.

The operating pressure may be between about 10-2 and 10-6 Torr.

In accordance with another broad aspect of the teachings described herein, a lithium-based battery may include a cathode assembly having a cathode current collector and a cathode reactive surface. A lithium anode assembly may include an anode current collector having aluminum and having a first side with a support surface. At least a first protective layer may be bonded to and may cover the support surface. The protective layer may include a protective metal and being electronically conductive. At least a first reactive layer may include lithium metal bonded to the protective layer and may be configured to contact an electrolyte when the anode assembly is in use. An electrolyte may be disposed between and may contact the cathode reactive surface and the anode reactive layer. The first protective layer may be disposed between the support surface and the reactive layer so that electrons can travel through the first reactive layer and first protective layer from the electrolyte to the anode current collector. The first reactive layer may be spaced from and at least substantially ionically isolated from the support surface, whereby diffusion of the reactive layer to the current collector is substantially prevented by the first protective layer thereby inhibiting reactions between the lithium metal and the current collector.

The first protective layer may be at least substantially ionically isolates the support surface from the electrolyte.

The electrolyte may include a solid electrolyte material that directly contacts that first reactive layer and does not directly contact the anode current collector.

The anode collector ay be encased by the protective metal and may be physically isolated from the electrolyte.

The current collector may include a continuous aluminum foil.

The aluminum foil may have a thickness of between about 1 and about 100 microns.

The aluminum foil may be configured as a continuous web that includes the support surface and physically supports the first protective layer.

The protective metal may include at least one of copper, nickel, silver, stainless steel and steel.

The first protective layer may be deposited onto the support surface via physical vapour deposition and bonds to the support surface.

The first protective layer may have a thickness of between about 1 and about 75,000 Angstroms.

The first protective layer may have a thickness of between about 200 and about 7500 Angstroms.

The first protective layer may have an isolation thickness and may be shaped so that the first reactive layer is completely ionically isolated from the current collector.

The protective metal may be unreactive with the lithium metal.

The protective metal may cover the entire first side of the current collector.

The first reactive layer may have a thickness of between about 0.001 and about 100 microns.

The first reactive layer may have a thickness of between about 0.01 and about 20 microns.

The first reactive layer may be deposited onto the first protective layer via physical vapour deposition and bonds to the first protective layer.

The anode assembly may be free of lithium metal foil.

The current collector may include an opposing second side and a second protective layer bonded to and covering the second side and including the protective metal.

A perimeter of the first protective layer may be joined to a corresponding perimeter of the second protective layer thereby sealing the current collector with the protective metal.

The first protective layer may be joined to a corresponding perimeter of the second protective layer via at least one of physical vapour deposition, application of a polymer film, application of a polymer resin and mechanical crimping of the perimeters.

A second reactive layer including lithium metal may be bonded to the second protective layer and may be configured to contact an electrolyte when the anode assembly is in use.

In accordance with another broad aspect of the teachings described herein, a roll-to-roll metallizing apparatus may include: a metallizing chamber having an interior that is configurable at an operating pressure that is less than about 0.001 kPa during a first vacuum cycle. A roll-to-roll winding assembly may be provided within the metallizing chamber and may include a first spindle supporting a first roll of foil for unwinding, a second spindle onto which foil can be wound and a first foil web travelling therebetween. A physical vapour deposition apparatus may be provided within the metallizing chamber and may be configured to, during the first vacuum cycle, treat the first roll of foil by independently depositing i) a layer of a protective metal onto the first foil web travelling between the first spindle and second spindle and ii) a layer of a reactive material onto the layer of protective material. An air-lock chamber may have an interior that is configurable at about the operating pressure during the first vacuum cycle and may be configured to simultaneously accommodate at least the first roll of foil and the second roll of foil. A chamber door may separate the interior of the metallizing chamber and the interior of the air-lock chamber. When the air-lock chamber is at a transfer pressure that is less than atmospheric pressure the chamber door may be movable between: a closed configuration in which the interior of the metallizing chamber is sealed and isolated from the interior of the air-lock chamber; and an open configuration in which the interior of the metallizing chamber is in communication with the interior of the air-lock chamber whereby the second roll of foil can be moved from the air-lock chamber into the metallizing chamber while maintaining the interior of the metallizing chamber at the transfer pressure. After the first roll of foil is removed from the metallizing chamber the second roll of foil may be mountable on the first spindle so that a second foil web extends between the first spindle and the second spindle and the second foil web may be treatable using the physical vapour deposition apparatus during the first vacuum cycle to deposit i) a second layer of a protective metal onto the second foil web travelling between the first spindle and second spindle and ii) a second layer of a reactive material onto the second layer of protective material.

When the chamber door is open the first roll of foil may be movable from the metallizing chamber into the air-lock chamber.

The transfer pressure may be less than about 0.01 kPa.

The transfer pressure may be substantially the same as the operating pressure.

The physical vapour deposition apparatus may also include: a first applicator configured to deposit the layer of a protective metal on the first foil web in a first deposition zone, and, a second applicator that is configured to deposit the layer of a reactive metal on top of the layer of protective metal.

The first foil web may travel in a travel direction when the first foil web is transferred from the first spindle to the second spindle, and the second applicator may be spaced from the first applicator in the travel direction.

The layer of reactive metal may be deposited in a second deposition zone that is spaced from the first deposition zone in the travel direction.

The physical vapour deposition apparatus may be configured to apply the layer of protective metal in a single pass of the first foil web through the first deposition zone.

The physical vapour deposition apparatus may be configured to apply the layer of reactive metal in a single pass of the first foil web through the second deposition zone.

The air-lock chamber may also include an air-lock door that can be movable independently of the chamber door between: a closed configuration in which the interior of the air-lock chamber is sealed and isolated from the ambient environment; and an open configuration in which the interior of the air-lock chamber is in communication with the ambient environment. When the chamber door is closed and the air-lock door is open the interior of the air-lock can be accessed from the ambient environment to while the metallizing chamber remains at the operating pressure.

A roll magazine apparatus may be disposed within the air-lock chamber and may be configured to receive the first roll of foil roll-to-roll winding assembly, simultaneously hold the first roll of foil and the second roll of foil, and then to transfer the second roll of foil from roll magazine apparatus to the roll-to-roll winding assembly while the metallizing chamber is maintained at the transfer pressure.

An inert repressurization system may be configured to repressurize the interior of the air lock chamber when the chamber door and air-lock door are closed to about atmospheric pressure using an inert gas that is inert relative to the reactive material.

A packaging apparatus may be within the air-lock chamber, and may be configured to receive the first roll of foil after it has been treated by the physical vapour deposition apparatus, and while the air-lock interior is repressurized with the inert gas, may be operable to seal the first roll of foil in a gas tight receiving container whereby the first roll of foil remains isolated from the air in the ambient environment when the receiving container is removed from the air-lock chamber.

### BRIEF DESCRIPTION OF THE DRAWINGS

Embodiments of the present invention will be described with reference to the accompanying drawings, wherein like reference numerals denote like parts, and in which:

FIG. 1A is schematic representation of a conventional lithium-ion cell;

FIG. 1B is schematic representation of a solid-state battery with a lithium anode;

FIG. 2 is schematic representation of one example of an anode assembly for use with lithium-based batteries;

FIG. 3 is an enlarged view of a portion of the anode assembly of FIG. 2;

FIG. 4 is perspective view of the anode assembly of FIG. 2;

FIG. 5 is schematic representation of another example of an anode assembly for use with lithium-based batteries;

FIG. 6 is a flow chart showing one example of a method of manufacturing an anode assembly;

FIG. 7 is a flow chart showing another example of a method of manufacturing an anode assembly;

FIG. 8 is a schematic representation of one example of a battery containing the anode assembly of FIG. 2;

FIG. 9 is a schematic representation of one example of an apparatus for manufacturing an anode assembly;

FIG. 10 is a cross-sectional view taken along line B in FIG. 9;

FIG. 11 is a cross-sectional view taken along line D in FIG. 9;

FIG. 12 is a cross-sectional view taken along line C in FIG. 9; and

FIG. 13 is a schematic representation of one example of a double-sided anode assembly.

### DETAILED DESCRIPTION

Various apparatuses or processes will be described below to provide an example of an embodiment of each claimed invention. No embodiment described below limits any claimed invention and any claimed invention may cover processes or apparatuses that differ from those described below. The claimed inventions are not limited to apparatuses or processes having all of the features of any one apparatus or process described below or to features common to multiple or all of the apparatuses described below. It is possible that an apparatus or process described below is not an embodiment of any claimed invention. Any invention disclosed in an apparatus or process described below that is not claimed in this document may be the subject matter of another protective instrument, for example, a continuing patent application, and the applicants, inventors or owners do not intend to abandon, disclaim, or dedicate to the public any such invention by its disclosure in this document.

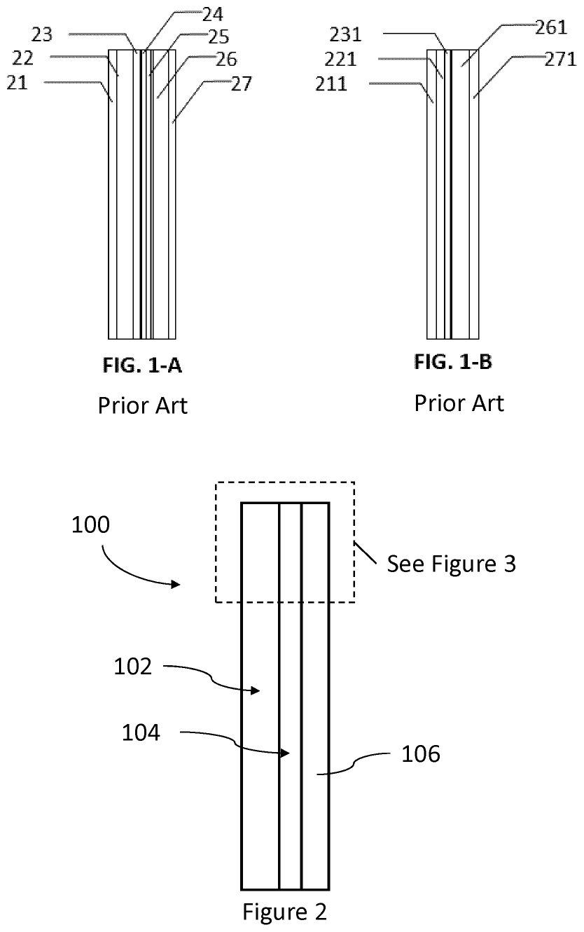

The demand for batteries is increasing due, in part, to the ever-growing demand for mobile electronic devices, grid storage and electric vehicles (EVs). These devices can be powered by conventional lithium-ion batteries (LIBs). Conventional lithium-ion batteries (LIBs) generally use electrochemical cells having a layered structure shown schematically in FIG. 1A and that for the purposes of the discussion herein can be understood to typically include:
A first current collector, typically a copper foil, 21;
An intercalation anode material, typically spherical graphite, applied to the first current collector, 22;
An anolyte, typically a fluorinated and lithiated hydrocarbon solvent, 23;
A lithium-ion permeable separator, typically a polymer sheet, 24;
A catholyte, typically a fluorinated and lithiated hydrocarbon solvent, 25;
An intercalation cathode material (Lithium Cobalt Oxide, Lithium Manganese Oxide, Lithium Iron Phosphate, Lithium Nickel Manganese Cobalt (NMC) and Lithium Nickel Cobalt Aluminum Oxide (NCA)), 26;
A second current collector, typically an aluminum foil, 27.

Existing LIBs can suffer from a number of shortcomings, including:
They are relatively costly to produce, relying on expensive materials such as cobalt, nickel, lithium and complex organic electrolytes.
They may have insufficient mass and volumetric energy density, owing at least in part to the low lithium ion storage capacity of the anode and cathode materials.
They can be relatively dangerous at least in part because damage to the cells or overheating of the battery packs can lead to rapid discharge and ignition of the highly flammable organic electrolytes.
As part of their manufacturing, they tend to require a lengthy period (typically around 40 hrs) of slow-charging before use, which requires substantially expensive facilities in the battery manufacturing plant dedicated to this process step.

New battery chemistries, including nickel and cobalt, such as those using NMC (nickel, manganese, cobalt) or NCA (nickel, cobalt, aluminium) cathodes, have been recently adopted to help address the problem of energy density. These may have relatively improved energy density by increasing cell voltage and decreasing cathode material quantity. This advance, while at least somewhat beneficial, leaves at least some of the safety and cost concerns described herein unaddressed, including, for example:
They generally rely on the same flammable electrolyte as previous batteries.
They generally rely increasingly on rare elements in the cathode materials.
They generally continue to require slow-charging facilities in the manufacturing plant.

In particular, the use of cobalt and nickel in the cathode can make these cathodes generally unsuitable for widespread application in EVs, because of their relatively high cost, and/or potential limitations associated with available cobalt resources which are insufficient to support demand at global adoption levels. Conversely, batteries which make use of less costly and more abundant minerals tend to suffer from relatively low energy density and do not resolve these safety concerns.

One approach which has be proposed to address the shortcomings of lithium-ion batteries is lithium metal battery solid-state battery (SSB). One schematic example of a battery of this type is illustrated in FIG. 1B and batteries of this type can typically include:
A first current collector, typically a copper foil, 211.
A lithium anode (which may simultaneously function as a current collector) typically a foil 25-100 microns thick 221.
A solid electrolyte, typically a lithium ion-conductive polymer, ceramic, or glass, 231.
An intercalation cathode material similar to those used in conventional LIBs, 261.
A second current collector, typically an aluminum foil, of 10-100 microns thick, 271.

This type of battery can help address a number of the challenges faced by conventional LIBS, including:
The lithium anode has the maximum physical lithium ion storage mass density, which is approximately six times higher than that of graphite.
The greater energy density afforded by the lithium anode can help offset the use of lower energy-density cathode materials, such as lithium iron phosphate, which are both less costly and rely on abundant elements.
The solid electrolyte eliminates the flammable solvents used in LIBs, greatly reducing the potential for fires due to thermal excursions or physical damage to the battery.
By constructing the battery such that all needed lithium is already on the anode (i.e., the battery cell is effectively charged during assembly), it is possible to eliminate the slow-charging step completely from the battery manufacturing process.

The adoption of SSBs may be hampered by the difficulty in creating suitable contact between the electrolyte and electrodes, and/or by the inherently, relatively high cost of lithium foils, both of which increase the final battery cost. Lithium foil anodes can be relatively costly to produce for a number of reasons:
Lithium metal can be costly at least in part because suitable feed materials required for its production are expensive to mine and refine.
The relatively low strength and density of lithium metal (as compared to other alternative metal foils) can make it relatively difficult to handle and roll to the small thicknesses desired for battery anodes.
Lithium metal reacts easily with air and moisture, which can make the handling and storage of the foils difficult.
The small scale of some current production methods inhibits the effect of economies of scale which normally reduce the cost of semi-finished products.

Additionally, lithium foils produced by extrusion have significant surface defects which can hinder deposition methods, thereby limiting the available production techniques for applying the solid electrolyte of SSBs.

The teachings described herein aim to help address at least the latter problem by helping to provide a suitable lithium anode that can reduce and/or eliminate the need for the use of a lithium foil. That is, the present teachings relate to an anode assembly that can be suitable for use in lithium metal solid-state and/or lithium ion batteries, and to a process and apparatus/equipment that can be used for its manufacture. Some aspects of the present disclosure can also relate to the production of relatively lower cost lithium anode assemblies for use in one or more types of lithium-based batteries, which, as used herein, can refer to both lithium solid state batteries (SSBs) and lithium ion batteries (LIBs) as well as other battery types that may be suitable for use with the anode assemblies described herein. The present teachings can also relate to a relatively low-cost production of roll-to-roll metallized substrates that can be used in the anode assemblies. According to certain non-limiting embodiments, the present disclosure may disclose a low-cost lithium anode and current collector assembly, a process for producing such an assembly, and physical vapor deposition equipment on which such a process can be operated. The teachings may also relate to batteries that include examples of the anode assemblies described herein.

In accordance with one embodiment described herein, an anode assembly for use in a lithium-based battery can include a current collector substrate that includes aluminum and has a support surface that is intended to receive/support other components of the assembly. A reactive layer that includes lithium metal is configured to contact an electrolyte within the battery when the anode assembly is in use and is generally supported by the current collector substrate. To help reduce the chances of an unwanted reaction between the reactive lithium layer and the aluminum in the current collector, the assembly can also include a suitable protective layer that is bonded to and covers the support surface and includes a protective metal that is suitably electrically conductive. In this arrangement the protective layer is disposed between the support surface and the reactive layer so that electrons can travel from the first reactive layer to the current collector and the first reactive layer is spaced from and at least substantially ionically isolated from the support surface. The protective layer can therefore help at least substantially prevent or inhibit, and may completely prevent diffusion of the reactive layer to the current collector which can help at least substantially inhibit, and optionally completely prevent unwanted reactions between the lithium metal and the current collector. This type of isolation between the current collector substrate and the reactive layer may help facilitate the use of lithium in the reactive layer while helping to facilitate the use of a material in the current collector that may be generally desirable to use as a current collector but that would otherwise (e.g. in the absence of a suitable protective layer) react with the lithium in the reactive layer in a manner that reduces the effectiveness of the anode assembly and/or that may damage or reduce the usefulness of the anode assembly or its sub-layers.

As used herein, the term layer describes the amount of a given material, such as the protective material, that is generally continuous and is not interrupted by intervening materials or structures. Any given layer may be formed by a single application of the layer material (e.g. a single pass of a physical vapour deposition process as described herein) that applies all of the material for a layer of a given thickness in a single step or process. Alternatively, a single layer as described herein may also be formed as the result/combination of two or more applications of the layer material (e.g. via multiple passes of a physical vapour deposition process as described herein) that each apply a portion of the layer material and the total layer thickness is measured on the layer formed by accumulating the material from the two or more applications.

The anode assemblies described herein may be fabricated via a number of processes, including electroplating, electroless plating, lamination, hot-dip metallizing, wave soldering and others, however, for reasons that will be made clear, a roll-to-roll vacuum metallizing (including electron beam or magnetron evaporation), or physical vapor deposition (PVD) process and equipment disclosed herein may offer an advantageous method of manufacturing the anode assembly of the present invention.

Existing commercial roll-to-roll metallizing equipment typically uses a vacuum chamber into which is loaded a roll of the desired substrate. The chamber is then evacuated to a pressure of 10⁻² to 10⁻⁶ Torr. A resistive, inductive, electron beam, or magnetron source then vaporizes metal as the roll is transferred from the drum onto which it was loaded, onto a receiving drum. When the entire roll has been metallized, the chamber is re-pressurized and the roll removed. A sputtering source may also be used to provide the physical vapor. In a typical cycle, 15-30 minutes are spent loading, 30-60 minutes evacuating, and 60-120 minutes metalizing, 5-10 minutes re-pressurizing and 15-30 minutes unloading, which results in an overall production availability of between 30% & 65%. These numbers are approximations only, and may not be the same for all machines.

Surface contaminants on the substrate to be treated, e.g. from handling material, can result in a relatively poor surface quality and adhesion of the coatings leading to re-work and relatively overall lower production rates and higher production costs. Oxidation and nitridation of lithium-based anodes, such as by atmospheric gases can damage the anode assembly, thereby increasing scrap and reducing productivity. Additionally, process which uses lithium foil as an input can be disadvantaged by the relatively high cost of this material.

Therefore, the teachings herein relate to an anode and anode production process that can achieves one or more of the following: avoids use of lithium foil, increases equipment availability and reduces re-work.

Another aspect of the teachings herein relates to a method for producing a multi-layer anode or anode assembly by depositing, via a PVD process, successive layers of unreactive and reactive metal and or other material (including a solid electrolyte membrane, comprising polymer, glass or ceramic films) onto a substrate, such that the deposition of such layers takes place within the same equipment without breaking vacuum, and thereby substantially reducing cycle time. This may help provide one or more of the following advantages over some known systems: the use of lithium foil can be avoided; the opportunities for contamination of substrates are reduced; handling and exposure to the atmosphere is also reduced; the utilization of the equipment can be increased; the energy costs associated with establishing a vacuum can be reduced. This may help provide a lower-cost anode assembly suitable for use in SSBs.

An apparatus for achieving some of these advantages may include a roll-to-roll vacuum metallizing equipment, having a vacuum metallizing chamber, a vacuum establishing means, two or more sources of vapourized metal, with at least one source for lithium metal, and one for an unreactive metal, a roll magazine, an airlock, a roll exchange means, a control system, and optionally, an inert gas containerizing system. Providing multiple sources of vapourized metal within a common vacuum metallizing chamber may help permit two or more different materials to be applied within the chamber without having to re-pressurize and evacuate the vacuum chamber between metal applications. This may save both availability and energy. Using a suitable airlock and magazine may help allow one or more additional sets of rolls to be loaded and evacuated while metallization of a roll is in progress. Once metallization is completed, the treated rolls can be replaced with new, untreated rolls without breaking vacuum (e.g. within a single vacuum cycle), thereby increasing availability of the equipment. An inert gas containerizing system can allow finished rolls to be placed and sealed in containers under an inert atmosphere without leaving the equipment, thereby reducing the possibility of contamination of the treated rolls or unwanted reactions between the reactive metal and gases (e.g. oxygen) in the atmosphere.

Referring to FIGS. 2-4, one example of an anode assembly 100 includes a current collector substrate 102, a reactive layer 106 and a protective layer 104 that is positioned between the collector 102 and the reactive layer 106 to at least substantially ionically isolate the reactive layer 106 from the current collector 102.

The current collector 102 can be formed from any suitable material, including known metal foils that are suitable for use in batteries as described herein. In this example the current collector 102 is formed from an aluminum foil. Unlike previously conceived lithium metal anodes, the inclusion of the protective layer 104 can allow the use of an aluminum foil material, which is a lower-cost conductive substrate than copper or other conventional materials, to be used as the current collector 102. This may help reduce the input material cost of the anode assembly 100, relative to assemblies that use other metals or polymers as collector substrates as done in the prior art. Other materials can be used for the collector if desired in some embodiments, copper, aluminium, nickel, stainless steel, steel, an electrically conductive polymer, a polymer and combinations thereof.

The current collector 102 has a front side 108 that is intended to face the electrolyte and cathode assembly when the anode assembly 100 is in use within a battery and an opposing rear side 110. The front side 108 can include a mounting portion or surface 112 that is the portion of the collector 102 that is bonded to and covered by the protective layer 104. The mounting surface 112 may cover all, or at least substantially all of the front side 108 as shown in this embodiment, or alternatively may cover less than 100% of the front side 108.

The current collector 102 may be formed from any suitable metal, and preferably can be formed from aluminum. In the present example, the collector 102 is formed from a continuous web of aluminum foil, but in other examples may have a different configuration. It is the presence of the protective layer 104 that can facilitate the use of aluminum foil as the current collector 102 and physical substrate that ultimately supports the lithium metal in the reactive layer 106. Preferably, the anode assembly 100 need only include the aluminum foil in the collector 102 as a continuous physical substrate to help support the other portions of the assembly 100, and can be formed without the need to use lithium foil or copper foil (e.g. can be free from lithium foil).

Using aluminum to form the collector 102 may have several beneficial characteristics that make it an excellent current collector. For example, from the available and suitable metals for forming a collector, aluminum may be volumetrically, one of the least costly metals. Aluminum can also be sufficiently strong as a thin foil to resist tearing during the manufacturing of the anode assembly 100 and can be relatively easier to roll, unroll and generally to handle in the manufacturing process as compared to other foils, such as lithium foil. Aluminum is also a sufficiently, and relatively efficient electrical conductor which can help ensure the anode assembly 100 functions as desired.

In fact, these characteristics may be some of the factors that lead to aluminum foil being used frequently in LIBs for the cathode current collector. However, aluminum has generally been considered unsuitable as an anode current collector as contemplated herein (generally because of its incompatibility with lithium metal when directly exposed). For example aluminum can be considered unsuitable for anode current collectors because it alloys readily with lithium under relatively small electropotentials. By displacing aluminum in the crystal structure, the lithium causes the current collector to swell significantly, leading to its degradation and eventual disintegration, thereby limiting the life of the battery. Because of this, aluminum has not used for this purpose in LIBs or for the anode current collector of SSBs to the inventors knowledge.

The current collector 102 in this example can be formed having any suitable size, shape and thickness as is suitable for use in a given battery design or similar application. For example, the collector 102 has a collector thickness 114 that can be between about 1 and about 100 microns, or more, depending on a given application.

Preferably, the aluminum foil used to form the current collector 102 can be provided as a continuous web of foil that is unwound from a first or source roll of aluminum foil and that can travel through a treatment or fabrication zone during a manufacturing process, in which the materials used to form at least one of (and preferably both of) the protective layer 104 and reactive layer 106 can be applied to the continuous foil web. In this arrangement, the aluminum collector 102, and the support surface 112 thereon, can physically support the protective layer 104 and/or reactive layer 106. This may help reduce and/or eliminate the need for the protective layer 104 and reactive layer 106 to be formed from continuous foils or webs and instead may allow the materials used to form the protective layer 104 and the reactive layer 106 to be directly deposited or otherwise applied to the support surface 112 of the collector 102. Some examples of a suitable manufacturing process of this nature are described herein.

The protective layer 104 is formed from any suitable protective material that can provide a desired degree of electronic conductivity between the reactive layer 106 and the collector 102 and that can also (when applied with a suitable thickness) ionically isolate the reactive layer 106 from the collector 102. The metal used to form the reactive layer 104 is also preferably completely, or at least substantially, inert with respect the both the material of the collector 102 and the material of the reactive layer 106 to help prevent galvanic corrosion or other unwanted reactions between the layers 102 and 104 or 104 and 106. The particular material used in a given assembly 100 may be influenced by the specific materials used to form the collector and reactive layer in that embodiment.

Some examples of suitable materials for forming the reactive layer 104 are typically metals, and can include copper, nickel, silver, steel, stainless steel, chromium, and other metals into which lithium from the reactive layer 106 does not readily intercalate or alloy (e.g. are sufficiently unreactive with lithium metal).

The protective layer 104 has a protective or isolation thickness 116 that can be selected to be any thickness that can sufficiently isolate the reactive layer 106 from the collector 102, and preferably is selected to be the minimum thickness that provides the desired degree of isolation. For example, thickness 116 may be between 1-75,000 Angstroms, and more preferably may be between about 1-15000 Angstroms thick, with a thickness of between about 200-7500 Angstroms being most preferred in some embodiments.

The thicknesses 114 and 116 of the collector 102 and protective layer 104 can be modified to achieve different battery characteristics. This may help provide some flexibility for the battery manufacturers to trade-off the capital and inventory costs associated with trickle charging, against the relatively higher anode costs associated with a thicker lithium coating. Such flexibility may allow manufacturers to tailor their production processes to suit the product needs and their business constraints.

Optionally, another metal layer, for example silver, gold, nickel or stainless steel, or any other suitable metal, can be introduced between the protective layer 104 and the current collector 102, for example to help improve bonding of the protective layer 104 to the aluminum foil in the collector 102.

The material forming the protective layer 104 may be applied to the collector 102 using any suitable technique. One suitable application technique is physical vapour deposition, in which the protective material can be provided as a suitable metal vapour that is deposited onto the support surface 112 as a thin, highly adhered and substantially pure metal (or alloy) coating. The protective layer 104 may be formed in one deposition pass/step, or may be built using two or more passes to build up a protective layer 104 having the desired thickness 116. This technique can allow the protective metal material to be bonded to the collector 102 without the need to use a separate bonding material, adhesive or the like.

The reactive layer 106 can be formed from any desirable material (including of lithium, potassium, rubidium, cesium, calcium, magnesium and aluminum), and in the examples described herein is formed from lithium metal. The reactive layer 106 is sized and shaped to provide the desired contact surface 120 for contacting the electrolyte material in a battery.

The reactive layer 106 can have any suitable thickness, and preferably may have a thickness that is between about 0.001 and about 100 microns, or may be between about 0.01 microns and about 20 microns.

A reactive layer 106 of this nature can be provided using any suitable technique, and preferably can be applied without the use of a lithium foil (e.g. is free from lithium foil, while containing lithium metal). In the present example, the reactive layer 106 is also applied via physical vapour deposition, in a second deposition process that is performed after the protective layer 104 has been deposited. Preferably, both deposition processes can be performed using a common machine, and can be done in the same processing chamber and under the same vacuum cycle, as described herein.

The anode assembly 100 can be further processed or combined with any suitable electrolyte material, including optionally a solid electrolyte, cathode, and other elements to produce a battery cell for use in an electric vehicle or electronic device.

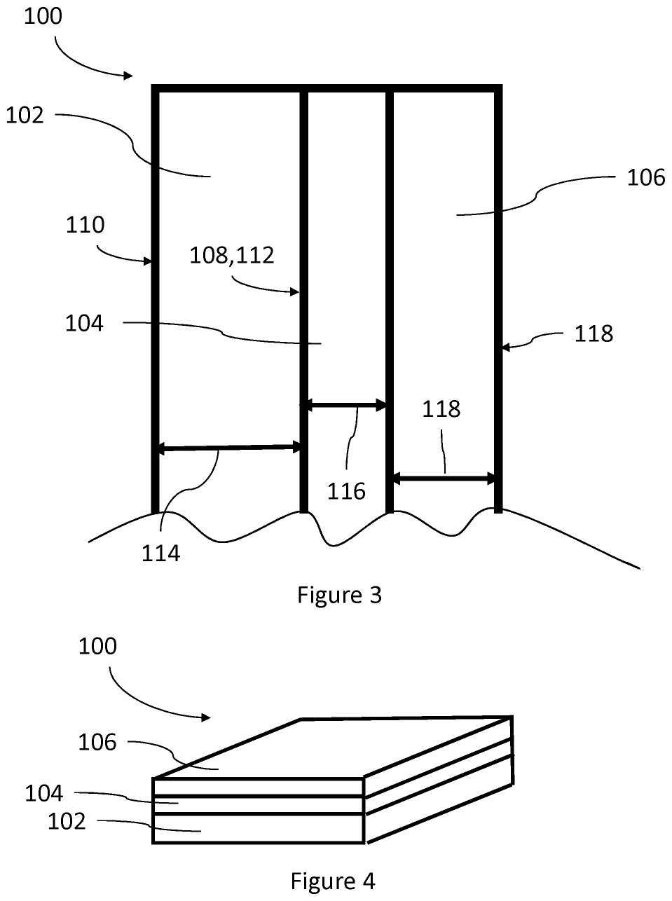

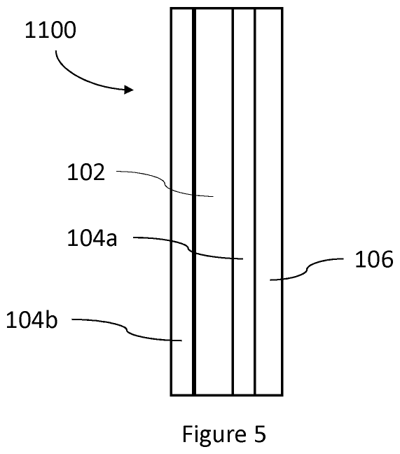

In the embodiment of FIGS. 2 and 3, the protective layer 104 is provided on the front surface 108 of the current collector 102. This may be adequate for some intended uses of the anode assembly 100, such as when used in a solid state battery and/or in combination with a solid electrolyte material that is only, or at least substantially only, in physical contact with the reactive layer 106. That is, by interposing the layer of protective metal between the lithium reactive layer and the aluminum collector 102, the aluminum collector 102 can be made substantially inert to the lithium in the reactive layer 106 which forms the outer, contact surface of the anode assembly 100. Because solid electrolyte batteries limit the conductive surface exposed to the electrolyte, the aluminum collector 102 would not typically share an ionic connection with the copper protective later 104 and so the assembly 100 is less susceptible to galvanic corrosion.

Alternatively, the collector 102 could be coated with the protective metal material on both sides such that another example of an anode assembly 1100 includes a first, front protective layer 104a on the front side 108 of the collector 102 (e.g. between the collector 102 and the reactive layer 106) and a second, rear protective layer 104b bonded to the opposing rear surface 110 of the collector 102. This may help prevent unwanted chemical reactions, such as galvanic corrosion from affecting at least substantially all of, and optionally all of the front and rear faces of the collector 102.

Optionally, the perimeters of the front protective layer 104a and the rear protective layers 104b could be joined to each other thereby effectively sealing the collector 102 within the protective material and generally ionically isolating the collector 102 from the surrounding environment. The protective layers 104a and 104b can be joined to each other using any suitable technique, including for example, PVD, polymer film or resin application, crimping and the like. Protecting at least the rear surface 108 of the collector 102, and optionally also protecting the side edges of the collector 102 by sealing the front and back layers 104a and 104b, may help facilitate the use of the anode assembly 1100 in batteries that use a non-solid electrolyte (e.g. liquid and/or gel, such as conventional LIBs, that may increase the likelihood of the rear surface 108 of the collector 102 being in contact with the electrolyte material.

The rear protective layer 104b may be formed using the same process use to form the from protective layer 104a (e.g. physical vapour deposition), or via a different process.

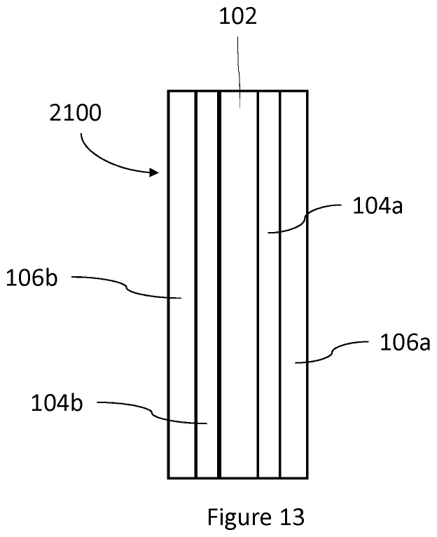

Optionally, some embodiments of the anode assemblies may be configured as double-sided anodes, in which both the front and back sides (or more generally the opposing first and second sides) of the current collector are coated with respective protective and reactive layers. One example of double-sided anode assembly 2100 is schematically illustrated in FIG. 13. In this example, the collector 102 has a first protective layer 104a on one side with a first reactive layer 106a applied to the first protective layer 104a. A second protective layer 104b is provided on the opposing, rear side of the collector 102 and is covered with a second reactive layer 106b. Optionally, as described above the protective layers 104a and 104b may be joined together, and in some examples the reactive layers 106a and 106b may be joined to each other in an analogous manner.

For exemplary purposes only, some comparative cost estimates are included below in Tables 1-7 with some estimates of the costs of the input materials used to make some conventional anode assemblies and an estimate of the costs of the input materials used in the anode assemblies described herein.

TABLE 1
Conventional Lithium Foil Anode Est. Cost (2019)

| | Material/ | Thickness | Unit Cost |
|---|---|---|---|
| | Method | (microns) | (USD/m²) |
| Current Collector | Li Foil | 12.5 | 6.675 |
| Active Anode | Li Foil | 20 | 10.68 |
| Processing | Single Piece | | 0 |
| Total Cost | | | 17.4 |

TABLE 2
Conventional Cu Foil and Li Foil
Anode Assembly Est. Cost (2019)

| | Material/ | Thickness | Unit Cost |
|---|---|---|---|
| | Method | (microns) | (USD/m²) |
| Current Collector | Cu Foil | 12.5 | 1.12 |
| Active Anode | Li Foil | 20 | 10.68 |
| Processing | Lamination | | 0.050 |
| Total Cost | | | 11.85 |

TABLE 3
Lithium Metal Anode Assembly Est. Cost (2019)

| | Material/ | Thickness | Unit Cost |
|---|---|---|---|
| | Method | (microns) | (USD/m²) |
| Current Collector | Cu Foil | 12.5 | 1.12 |
| Protective Layer | None | 0 | 0.00 |
| Active Anode | PVD Li | 20 | 1.63 |
| Processing | PVD | | 0.73 |
| Total Cost | | | 3.48 |

TABLE 4
Low-Cost Lithium Metal Anode Assembly According
to Present Disclosure Est. Cost (2019)

| | Material/ | Thickness | Unit Cost |
|---|---|---|---|
| | Method | (microns) | (USD/m²) |
| Current Collector | Al Foil | 12.5 | 0.17 |
| Protective Layer | Cu | 0.015 | 0.001 |
| Reactive Layer | PVD Li | 20 | 1.63 |
| Processing | PVD | | 0.40 |
| Total Cost | | | 2.21 |

TABLE 5
Thin Lithium Metal Anode Assembly (For
Trickle-Charging) Est. Cost (2019)

| | Material/ | Thickness | Unit Cost |
|---|---|---|---|
| | Method | (microns) | (USD/m²) |
| Current Collector | Cu Foil | 12.5 | 1.12 |
| Protective Layer | None | 0 | 0.00 |
| Active Anode | PVD Li | 0.1 | 0.01 |
| Processing | PVD | | 0.00 |
| Total Cost | | | 1.13 |

TABLE 6
Thin Low-Cost Lithium Metal Anode Assembly According to Present
Disclosure (For Trickle Charging) Est. Cost (2019)

| | Material/ | Thickness | Unit Cost |
|---|---|---|---|
| | Method | (microns) | (USD/m²) |
| Current Collector | Al Foil | 12.5 | 0.17 |
| Protective Layer | Cu | 0.015 | 0.001 |
| Reactive Layer | PVD Li | 0.1 | 0.01 |
| Processing | PVD | | 0.003 |
| Total Cost | | | 0.18 |

TABLE 7
Approximate Costs for Current Collector Substrate Materials (Est. 2019)

| | | | | | Stainless | PVDF | | |
|---|---|---|---|---|---|---|---|---|
| | Aluminum | Nickel | Copper | Lithium | Steel | (resin) | Silver | Gold |
| Density | 2700 | 8900 | 8960 | 534 | 8000 | 1780 | 10500 | 19320 |
| (kg/m³) | | | | | | | | |
| Material Cost | 1.875 | 13.165 | 6.5 | 150 | 3.3 | 8 | 487 | 43408 |
| (USD/kg) | | | | | | | | |
| Substrate Cost | 0.05 | 1.17 | 0.58 | 0.80 | 0.27 | 0.14 | 51 | 8386 |
| (USD/m² @ 10 | | | | | | | | |
| microns thick) | | | | | | | | |

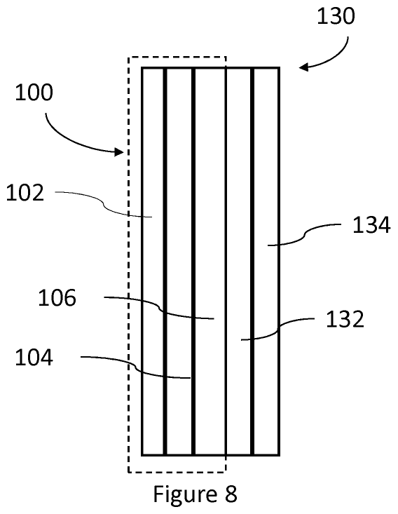

The anode assemblies 100 and 1100 can be used in combination with other components to provide a lithium-based battery that includes any suitable cathode assembly comprising a cathode current collector and a cathode reactive surface along with a lithium anode assembly as described herein. An electrolyte can be disposed between and can contact the cathode reactive surface and the anode reactive layer, and the first protective layer can be disposed between the support surface and the reactive layer so that electrons can travel through the first reactive layer and first protective layer from the electrolyte to the anode current collector. The first reactive layer can be spaced from and at least substantially ionically isolated from the support surface whereby diffusion of the reactive layer to the current collector is substantially prevented by the first protective layer thereby inhibiting reactions between the lithium metal and the current collector. That is, the first protective layer can at least substantially ionically isolate the support surface from the electrolyte. One schematic example of a battery 130 is shown in FIG. 8, and includes the anode assembly 100 in combination with a schematic representation of an electrolyte 132 and suitable cathode assembly 134.

Depending on the battery design the electrolyte may include a solid electrolyte material that directly contacts that first reactive layer and does not directly contact the anode current collector, or may include a different type of electrolyte material. Preferably, the anode collector (e.g. collector 102) is encased by the protective metal in the protective layer(s) 104 and is physically and ionically isolated from the electrolyte.

The anode assemblies described herein may be manufactured using any suitable manufacturing process, including those described herein. Preferably, the manufacturing process can utilize at least two physical vapour deposition processes to apply the protective and reactive layers 104 and 106 onto the collector 102, and more preferably can be conducted in at least a semi-continuous process in which the payers 104 and 106 are depositing on a moving aluminum foil web in a roll-to-roll process. As physical vapour deposition is to be conducted at low pressure/vacuum conditions, the manufacturing process can preferably be configured so that both the protective and reactive layers 104 and 106 are deposited onto the collector 102 within a common apparatus/metalizing chamber and while under the same vacuum cycle and conditions. This may help reduce or eliminate the need to break the vacuum conditions between depositing the protective layer 104 and the reactive layer 106, which can help shorten the manufacturing time and/or reduce the amount of energy required to re-create a second vacuum condition when depositing the reactive layer 106. Optionally, the completed material (e.g. the collector 102 with protective and reactive layers 104 and 106) can be wound onto an output roll at the end of the roll-to-roll process and preferably the output roll can then be packaged and/or otherwise treated while still within the same vacuum chamber to that the packaging and/or treatment can be completed before the output roll is exposed to oxygen in the ambient environment.

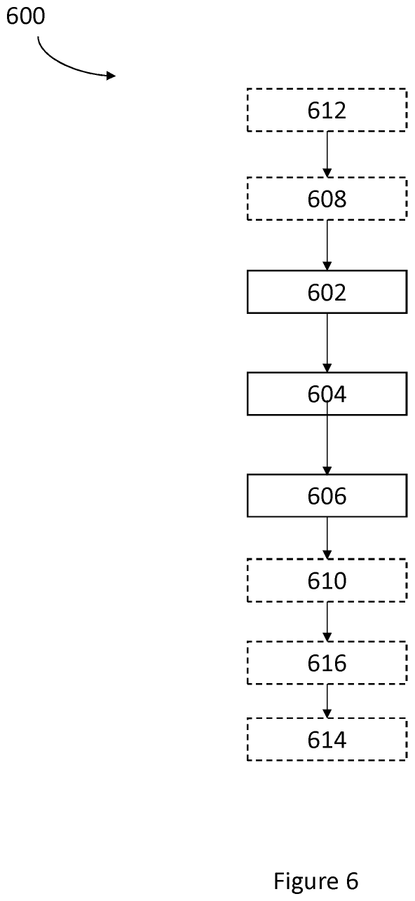

Referring to FIG. 6, one example of a method of manufacturing an anode assembly 600 includes, at step 602 providing a metallic, current collector substrate (e.g. collector 102) within the interior of a metalizing chamber that can be configured at atmospheric pressure and can selectively be configured (such as by using a suitable vacuum pump apparatus or the like) to have an interior operating pressure that is less than atmospheric pressure. The operating pressure in the metallizing chamber can be any suitable pressure that facilitates the desired physical vapour deposition process, and can be between about 10⁻² and 10⁻⁶ Torr in some examples. Preferably, this can provide an interior the metalizing chamber that is substantially free of oxygen while the layers 104 and 106 are formed.

At step 604, the support surface 112 on the collector 102 is at least partially coated with the protective metal material via a first physical metal deposition process, using one or two or more passes, to build up and provide the protective layer 104.

At step 606 the protective layer 104 is at least partially coated with the reactive metal material via a second physical metal deposition process, using one or two or more passes, to build up and provide the reactive layer 104, whereby the first protective layer 104 is disposed between the support surface 112 and the reactive layer 106 so that electrons can travel from the first reactive layer 106 to the current collector 102 and the first reactive layer 106 is spaced from and at least substantially ionically isolated from the support surface 112, and whereby diffusion of the reactive layer 106 to the support surface 112 is prevented by the first protective layer thereby inhibiting reactions between the reactive metal and the current collector 102.

Preferably, the collector 102 material is a continuous, metallic foil that is unwound from a first input roll prior to step 602, via optional step 608, and then wound onto a first output roll after step 606, via optional step 610. In this arrangement, steps 604 and 606 can preferably be carried out while the continuous, metallic foil web is moving between the first input roll and the first output roll.

The first, and subsequent input rolls can be supported by any suitable unwinding apparatus that preferably is also located within the low pressure metalizing chamber so that the roll can be unwound and the web accessed while maintaining the vacuum in the chamber. Similarly, the output roll can be held on a suitable winding apparatus that preferably is also located within the low pressure metalizing chamber so that the output roll can be wound while maintaining the vacuum in the camber. The web may move between the input and output rolls at any suitable processing speed that allows the desired deposition processes to be successfully completed, and may be between about 20 and about 1500 m/min.

Optionally, step 604 can include providing the protective metal from at least one protective metal vapour source apparatus, such as a protective metal vapour source that is configured to deposit between about 0.001 and about 10 microns of the protective metal on the support surface 112 in a single pass while the web is moving at the processing speed. This deposition process may then be repeated if needed, for example by reversing the travel of the web and then passing the previously coated portions of the support surface 112 past the protective metal vapour source for a second and/or subsequent pass and depositing the protective metal onto the support surface 112 until the first protective layer has as thickness of between about 1 and about 75,000 Angstroms.

Optionally, step 606 can include providing the reactive metal from at least one reactive metal vapour source apparatus, such as a reactive metal vapour source that is configured to deposit between about 0.001 and about 10 microns of the reactive metal on protective layer 104 in a single pass while the web is moving at the processing speed. This deposition process may then be repeated if needed, for example by reversing the travel of the web and then passing the previously coated portions of the protective layer 104 past the reactive metal vapour source for a second and/or subsequent pass and depositing the reactive metal onto the protective layer 104 until the first reactive layer has as thickness of between about 1 and about 20 microns. Preferably reactive metal vapour source can be spaced apart from, and optionally can be downstream from the protective metal vapour source in the direction of web travel. This may allow both the protective layer 104 and reactive layer 106 to be formed in a single pass of the collector web, provided that reactive metal vapour source and protective metal vapour source are operated to deposit a sufficient amount of their respective metals in a single pass.

Optionally, prior to beginning to unwind the collector web and begin the deposition processes the method 600 can include, at step 612, reducing the pressure in the interior of the metalizing chamber from generally atmospheric pressure to the operating pressure and then introducing the first input roll into the interior of the metalizing chamber via an airlock whereby the first input roll can be conveyed from outside the metalizing chamber to inside the metalizing chamber without increasing a pressure in the interior of the metalizing chamber above 1 kPa. Preferably, the pressure in the airlock can be reduced to a suitable transfer pressure that is less than about 10⁻² torr and preferably substantially matches the operating pressure prior to opening the chamber door to join the chambers, but in some examples the transfer pressure in the air lock may less than atmospheric pressure but may still be higher than the operating pressure. This may help allow the metallizing chamber to be maintained at, or at least substantially close to the operating pressure while new rolls of collector foil are brought into the chamber without breaking the vacuum—e.g. during the same vacuum cycle. A vacuum cycle can be understood to include a substantial depressurization of the metallizing chamber (such as from about atmospheric pressure to close to or to the operating pressure), an operating period at which the chamber is held at substantially the operating pressure and the metal deposition can take place, and then a subsequent re-pressurization of the metallizing chamber to a pressure that is substantially greater than the operating pressure and under which the deposition processes may not function as intended (such as returning from the operating pressure to about atmospheric pressure, or other increases of about 50 kPa or more). Minor difference in the air-lock pressure or transfer and metallizing chamber pressures during the transfer of rolls of foil may require a small correction to the metallizing chamber pressure when the transfer is complete, but such pressure differences will preferably be less than about 10⁻² torr, and preferably less than about 10⁻⁶ torr or less and can be considered to be within the same vacuum cycle for the purposes of the teachings herein. Because pressurizing and depressurizing the metallizing chamber may take time and require additional energy inputs to drive a suitable vacuum apparatus, incorporating an air-lock as described herein can reduce the amount of time it takes to introduce a new foil roll into the metalizing chamber because it is not necessary to break vacuum and then restore the vacuum conditions within the metalizing chamber (e.g. it can allow two or more rolls of foil to be treated by the physical vapour deposition apparatus within a single vacuum cycle of the metallizing chamber).

Similarly, the method 600 can include the optional step 614 in which the first output roll (holding the completed assembly materials) can be removed from the interior of the metalizing chamber via an airlock (optionally the same airlock or a different airlock that was used to introduce the input roll) whereby the first output roll can be conveyed from inside the metalizing chamber to outside the metalizing without increasing a pressure within the interior of the metalizing chamber above about 10⁻² torr. Preferably, the pressure in this airlock can be reduced to match the operating pressure prior to opening the airlock door to join the chambers, but in some examples the pressure in the air lock may be less than atmospheric pressure but may still be higher than the operating pressure. This may help allow the metallizing chamber to be maintained at, or at least substantially close to the operating pressure while new rolls of collector foil are brought into the chamber without breaking the vacuum. This can reduce the amount of time it takes to remove the output roll from the metalizing chamber because it is not necessary to break vacuum and then restore the vacuum conditions within the metalizing chamber.

Preferably, steps 612 and 614 can utilize a common airlock chamber as this may help reduce the complexity of the machine. Optionally, after depleting the first input roll a new, second input roll can be moved from a roll magazine/holding apparatus that is disposed within the airlock (e.g. in the low pressure region) and into the interior of the metalizing chamber via the airlock and without increasing a pressure in the interior of the metalizing chamber above 1 kPa (and preferably while keeping it at about the desired operating pressure). Steps 608-612 can then be repeated using the metallic substrate unwound from the second input roll.

The method can also include an optional packaging step 616 during which first output roll can be packaged, treated and/or sealed while still contained within the air tight, low pressure interior of the metalizing chamber, or of the airlock, or within an air tight interior of a separate receiving chamber having an interior that is substantially free of oxygen prior to removing the first output roll from the airlock. This can help reduce the chances of the finished anode assemblies being exposed to oxygen.

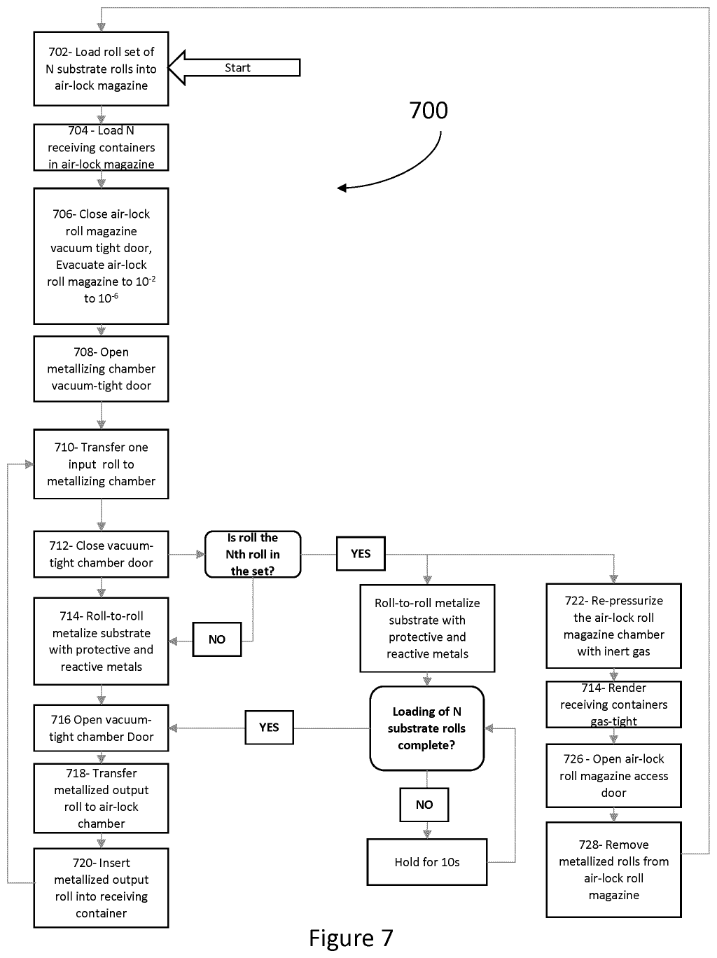

Referring to FIG. 7, another example of a method 700 of producing an anode assembly for a solid-state battery via a roll-to-roll physical vapour deposition process that uses vapour sources for both the protective metal and the reactive metal in a single metallizing chamber is shown. In this example the processes of depositing the protective metal and the reactive metal can both be completed within a single vacuum cycle of the metalizing chamber. That is, the pressure in the metalizing chamber can be lowered to the operating pressure and both the deposition of the protective metal and reactive metal can be completed before the vacuum in the metalizing chamber is released and it returns to atmospheric pressure. This is in contrast to a process in which the pressure in the metalizing chamber is lowered, the protective metal is deposited, the pressure in the metalizing chamber is raised (for example to allow access to the chamber or to remove the partially treated aluminum foil) and then the pressure is reduced again in order to deposit the reactive metal.

Preferably, to help allow for the removal of the completed, output rolls and their replacement with fresh input rolls containing aluminum foil that is yet to be coated, an air-lock that is separate from, but in communication with the metalizing chamber can be used to help facilitate roll exchanges without releasing the vacuum in the metallizing chamber during the roll changes.

In this example of the method 700, step 702 includes loading a first set of aluminum foil rolls into an air-lock magazine chamber that is adjacent a metalizing chamber. Each set of rolls described herein contains at least one input roll of aluminum foil that is to be treated/coated and preferably may include multiple input rolls that can be treated sequentially. For the purposes of providing an example the method will be described using a set of N number of input rolls.

Step 704 includes positioning a set of receiving containers, containing at least one receiving container that is configured to receive at least one output roll within the air-lock chamber. At step 706 the externally accessible air-lock chamber access door can be sealed and the air-lock chamber is evacuated to a first, operating pressure of 10⁻² to 10⁻⁶ Torr.

A vacuum-tight chamber door that separates the air-lock chamber from the metalizing chamber can then be opened at step 708 to provide communication between the interior of the air-lock chamber and the interior of the metalizing chamber that is preferably already at, or about the operating pressure.

At step 710 an input roll containing aluminum foil is then transferred from the air-lock chamber and into an evacuated metallizing chamber held at its operating pressure of 10⁻² to 10⁻⁶ Torr. The vacuum-tight chamber door can then be closed and made gas tight to isolate the interior of the metalizing chamber from the interior of the air-lock chamber, at step 712.

With the metalizing chamber now in its use or operating configuration, the aluminum foil can then be unrolled from the input roller and rolled onto a receiving spool or spindle at a web speed between about 20-1,500 m/min at step 714. As the web of aluminum foil is moving it can pass through a first deposition zone in which the protective material, e.g. copper in this example, can be deposited onto the aluminum foil from a protective metal vapour source that is preferably capable of depositing 0.001-10 microns/pass, and preferably 0.1-1 microns/pass, at the web speed. If needed, the winding and unwinding in this step can be repeated two or more times to help achieve the desired protection thickness of 1-75000 Angstroms.

Having completed the deposition of the protective metal, the this step 714 can also then include additional winding and unwinding of the aluminum foil and moving it through a second deposition zone in which the reactive metal, e.g. lithium, is deposited on top of the protective layer using a reactive metal vapour source that is preferably capable of depositing 0.001-10 microns/pass, at the web speed. This can be continued/repeated until the desired reactive layer thickness is achieved.

When the aluminum foil has been coated with both the protective and the reactive metal then the vacuum-tight chamber door of the air-lock chamber can be opened so as to re-establish communication between the metallizing chamber and air-lock chamber, at step 716.

Step 718 can then include transferring what can now be considered an output roll that includes the coated foil into the air-lock chamber and step 720 that includes placing the output roll into the receiving container while the air-lock chamber is still under vacuum conditions (e.g. at or near the operating pressure).

The steps 708 to 716 can then be repeated for the next input roll that is waiting within the roll storage magazine within the air-lock chamber, and can continue to be repeated until the last of the N rolls in the magazine has been treated in the metalizing chamber and returned to the air-lock chamber.

When the last roll of foil in the current set has been coated and returned to the air-lock chamber, the method 700 can then proceed to step 722 in which the air-lock chamber can be re-pressurized and returned to about atmospheric pressure using any suitable repressurization system that is configured to repressurize the interior of the air lock chamber. Preferably, this can be done using an inert gas (e.g. a gas that is inert relative to the reactive material), such as argon, neon, helium, xenon, krypton to help reduce exposure of the coated rolls to oxygen. With the pressure restored to about atmospheric the receiving container(s) (optionally one container can be provided per roll, or two or more rolls may be held in one container) can then be sealed in a gas/air tight manner at step 724.

Having sealed the coated rolls within their containers, the air-lock chamber access door can be opened at step 726 and the receiving containers, with the coated rolls sealed therein can be removed from the air-lock chamber at step 728 and transported for further processing.

If a second set of N rolls are to be treated the method 700 can then restart at step 702 for the second set of aluminum foil rolls, with the loading of the new N number of rolls into the air-lock magazine chamber.

The equipment used to carry out the methods described herein can be configured, and preferably optimized, so as to help ensure that the size of the magazine region in the air-lock chamber is such that its re-pressurization, unloading, re-loading and de-pressurization can be carried out in substantially the amount of time required to metallize one roll of foil. In doing so, metallization operations can be carried out in a substantially continuous fashion, thereby avoiding the downtime associated with conventional machines in which the metalizing chamber re-pressurizes and depressurizes when transitioning between each roll, and hence increasing machine productivity by approximately 35% to 65%. This may help facilitate an increase in productivity that may allow for a reduction in the cost of anode assembly production.

Similarly, the methods of operation of the present disclosure may help reduce energy consumption associated with vacuum pumping by reducing the total volume that needs to be evacuated per roll of processed substrate. Since the transfers of rolls between the magazine air-lock and the metalizing chamber are done under vacuum (e.g. at about the operating pressure), this may also help reduce the amount of foreign material, in the form of dust and other contaminants, that is introduced into the metallizing chamber during the loading and unloading process, which may help reduce the generation of scrap, and thus further increase the productivity of the system.

It may be possible, in some examples to sequentially apply the reactive and unreactive metal coatings during the same rolling operation (i.e. in a single pass of the web), provided that the total mass flux of each metal is sufficient to deposit the desired thickness of each respective metal in one pass.

It will be appreciated by those skilled in the art that the processes described herein have not described every single optional operation or equipment that may be performed or used when treating/coating the rolls, such as certain surface preparation steps, such as plasma cleaning, flame treatment, corona discharge, or tacky roller contact, or instrumentation, such as pressure sensors, tension sensors, and gas analyzers, or miscellaneous equipment, such as cooled deposition drums, idler rollers, and rewinding rolls, that are commonly used in vacuum metallizing systems. Such processes and equipment have been omitted for clarity, and are considered to be incorporated as needed herein.

Optionally, the methods described herein may also be supplemented to include additional vapour deposition sources, or other deposition sources suitable for applying a film to the roll. Such processes could, for example apply additional bonding layers, or solid electrolyte layers, cathode layers and cathode collector layers onto the coated aluminum foil webs while still being operated within the same metallizing chamber and without having to re-pressurize the chamber between sequential operations/coatings.

The methods described herein can be modified and applied to other suitable reactive metal metallizing process of substrates such as copper, nickel, stainless steel, conductive polymers, or non-conductive polymers.

The methods described herein can be applied to other suitable reactive metal metallizing process, where layered structures are produced for applications and need not be limited only to the production of anode assemblies.

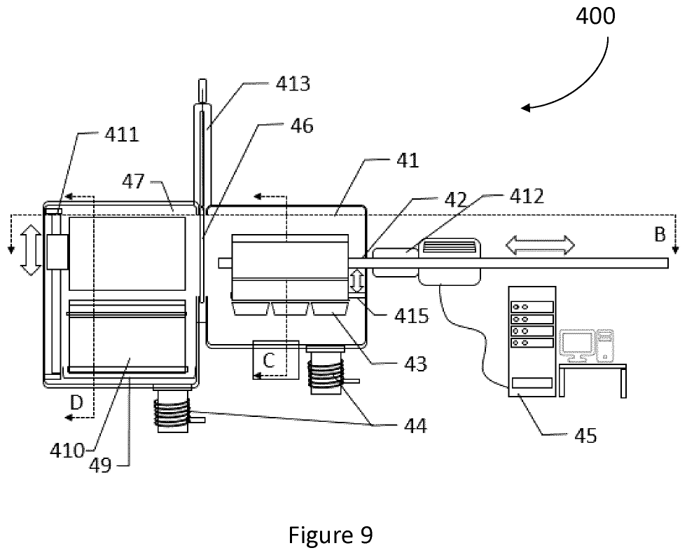

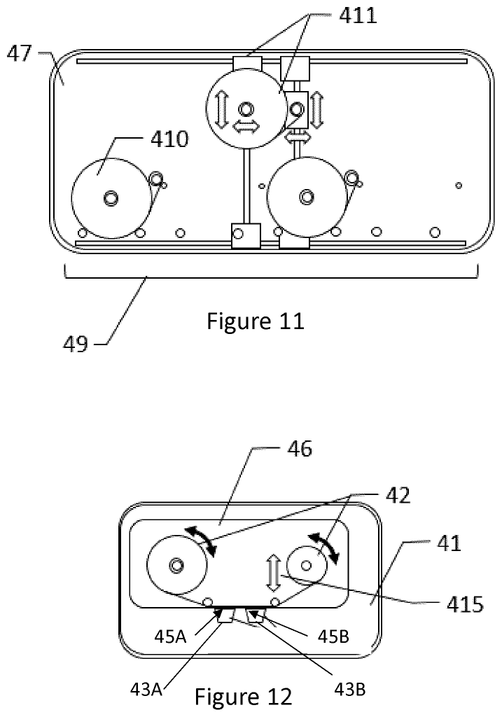

The anode assemblies and methods described herein can be produced using any suitable apparatus that can include a variety of different components and sub-systems as appropriate. One example of an apparatus that can be used to produce the anode assemblies described herein is described below and is schematically illustrated in FIGS. 9-12. These schematic illustrations show how aspects of the apparatus can be arranged to work together, but for clarity do not include illustrations of every piece of hardware, etc. that would be included in a production version of the apparatus.

In this example, a roll-to-roll metallizing apparatus 400 includes a metallizing chamber 41 having an interior that is configurable at an operating pressure that is less than about 0.001 kPa during a first vacuum cycle. A roll-to-roll winding assembly is located within the metallizing chamber and in this example includes first and second reversible driven roll spindles 42. A vacuum pumping system 44 that is preferably capable of achieving the desired operating pressures 10⁻²-10⁻⁶ Torr of vacuum is connected to the metallizing chamber and can be controlled by any suitable controller 45, which in this example includes a computer control system 45 (but could include other controllers, such as PLCs and the like and may also include any desired sensors, transducers and user input/output devices). The controller 45 can be configured to control typical parameters such as roll speed, source intensity, vacuum, roll direction, etc. Unlike conventional control systems, the controller may also control the air-lock cycles through position encoders, vacuum gauges, etc., and the roll exchange cycle processes.

The chamber 41 is bounded by chamber walls and includes at least one openable chamber door, shown as door 46, through which rolls of foil can be introduced into the metallizing chamber 41. The vacuum metallizing chamber 41, vacuum pumping system 44 and reversible roll spindles 42 are shown schematically for reference and can be of any suitable design for a given example of this apparatus 400.

The apparatus 400 can also optionally be equipped with tensioners, idling rollers, typical sensors and/or suitable pre-treatment equipment (roll cleaning, plasma cleaning, corona treatment, etc.), as desired, which equipment can be incorporated as appropriate but is not shown in the current figures for clarity.

In this example the treated rolls of foil are also removed via the same door 46, but in other examples the chamber 41 may have two or more separately located and openable chamber doors.

A physical vapour deposition apparatus is also positioned at least partially within the metallizing chamber and is configured to, during the first vacuum cycle, treat the roll of foil within the chamber 41 by independently depositing i) a layer of a protective metal onto a first foil web travelling between the first and second spindles 42 and ii) a layer of a reactive material onto the layer of protective material. In the illustrated example the physical vapour deposition apparatus includes metal vapour sources 43, including protective applicator 43A (FIG. 12) that can apply the protective material and a reactive applicator 43B that can apply the reactive material. These applicators 43A and 43B are spaced apart from each other in the direction that the web of foil will travel when moving between the spindles 42 (as described herein) with the region above each applicator 43A and 43B defining respective deposition regions 45A and 45B on the foil web. In this example the deposition regions 45A and 45B are also spaced apart from each other and are registered above their respective applicators 43A and 43B. In other examples the deposition regions may at least partially overlap each other. The sources of applicators 43 can be any suitable type including, for example, resistance or induction-heated boats, jet sources, magnetron sources, electron beam sputtering sources and similar. These are selected and sized according to known principles, depending on the desired rate of deposition, required coating adhesion, etc.

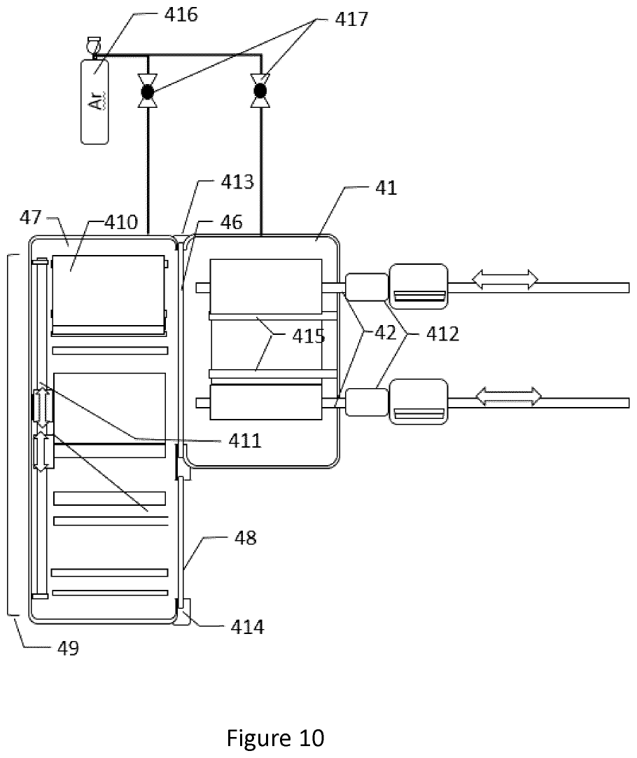

An air-lock chamber 47 is shown next to the metallizing chamber 41 and has an interior that is configurable at about the operating pressure during the first vacuum cycle and can configured to simultaneously accommodate at least two rolls of foil while the apparatus is in use. The air-lock chamber 47 is bounded by suitable sidewalls and can include an air-lock chamber door 48 that is movable between a closed configuration in which the interior of the air-lock chamber 47 is sealed and isolated from the ambient environment (as shown in FIG. 10) and an open configuration in which the interior of the air-lock chamber 47 is in communication with the ambient environment. In this arrangement, when the chamber door 46 is closed and the air-lock door 48 is open the interior of the air-lock 47 can be accessed from the ambient environment (such as to load or unload rolls of foil) while the metallizing chamber 41 need not be opened and can remain at the operating pressure and/or in use.

In this arrangement, the chamber door 46 can be movable to a closed configuration in which the interior of the metallizing chamber 41 is sealed and isolated from the interior of the air-lock chamber 47; and an open configuration in which the interior of the metallizing chamber 41 is in communication with the interior of the air-lock chamber 47 whereby after a first roll of foil has been treated a second roll of foil can be moved from the air-lock chamber 47 into the metallizing chamber 41 while maintaining the interior of the metallizing chamber at the transfer pressure and within a common vacuum cycle.

Optionally, a roll magazine that is capable of holding, and preferably moving and manipulating at least two or more rolls of foil can be provided within the air-lock chamber 47. In this schematic example, a roll magazine a roll magazine 49 is shown and is configured to be able to hold at least one roll pair 410 and also includes and a roll transfer apparatus for moving and manipulating the rolls. In this example, the roll transfer apparatus includes a multi-axis pick-and-place system 411, and a spindle extension mechanism 412.

Unlike conventional roll-to-roll metallizers, the metallizing chamber 41 is preferably accessible through the door 46 at an end of the chamber 41. End access may help facilitate a simplified layout for the roll magazine 49 and air lock chamber 47, as the door 46 is positioned such that it is intersected by the axes of the spindles 42 and the rolls can be loaded and/or unloaded from the spindles 42 by translating them along the axial direction of the spindles 42.

The airlock chamber 47 in this example, is of similar construction to the metallizing chamber 41, except it is preferably sized and shaped to accept two or more roll pairs 410 and a stationary, rotary or linearly-translating roll magazine 49. The air-lock chamber 47 communicates with the metallizing chamber 41 via the chamber door 46, which is sealed with an appropriately designed vacuum-tight sealing mechanism when closed, such as a vacuum-rated actuated gate valve 413. The air-lock chamber door 48 can also be sealed with an appropriately designed vacuum-tight sealing mechanism, such as a vacuum-rated actuated gate valve 414.

The airlock chamber 47 is equipped with a roll transfer means, comprising a two-axis pick-and-place system 411, mounted on the back face of the airlock chamber, and the spindle extension mechanism 412 in the metallizing magazine.

Preferably, the pick-and-place system 411 interfaces with the end of the foil roll spools, as shown in this example. This may help the pick-and-place system 411 to individually access each roll pair 410 in the roll magazine 49 and move it into place for loading. The pick-and-place system can preferably allow the two rolls of the roll pair to be moved independently. This allows the rolls in the magazine 49 to be stored in a relatively compact configuration and expanded for loading onto the roll spindles 42 in the metallizing chamber 41.

Once a roll pair is placed into loading position, chamber door 46 can be opened, allowing communication with the metallizing chamber 41. The roll spindles 42 can be axially extended into the airlock chamber using the spindle extension mechanism 412, where they interface with the spool bore of the roll pair 410. The pick-and-place mechanism 411 can then release the roll pair 410, and the spindles 42 can engage the roll pair 410 using any suitable locking mechanism. The spindles 42 can then be retracted into the metallizing chamber 41 using the spindle extension mechanism 412, or other suitable device.

Preferably, the vertically-actuated idlers 415 can then be move downwards, tensioning the foil web that extends between the spindles 42 and bringing it into close proximity to the metal vapor sources 43. Once the chamber door 46 is once again closed and sealed the metallizing of the given roll of foil can then proceed.

This arrangement can also allow metallized roll pairs to be withdrawn from the reversible roll spindles, placed in the magazine, and an un-metallized roll pair to be introduced into the metallizing chamber, without breaking vacuum (e.g. during a common vacuum cycle), thereby saving pressurization-related downtime and its attendant costs and loss in productivity.

A similar approach can be used to unload a roll pair from the metallizing chamber 41 when metallizing is complete, and to place it back into the roll magazine 49 within the air-lock chamber 47. The pick-and-place 411 system is preferably also used to transfer rolls from roll-pair magazine to the ambient environment; however, communication is through the air-lock chamber door 48. Loading can be performed automatically from automated loading spindles, or similar equipment, or manually from an appropriately modified forklift or other similar equipment.

Optionally, prior to opening door 48 and unloading, the air-lock chamber is re-pressurized with an inert gas (e.g. non-reactive with the lithium or other reactive metal used) using any suitable repressurziation system. In this example the repressurziation system includes an inert gas (e.g., argon) source 416 and a distribution system having any suitable flow control mechanisms, such as control valves 417. This can help prevent atmospheric air from be drawn into the air-lock chamber 47 and reacting with, the newly metallized material. Preferably, the rolls can be further protected with an automatic bagging or containerizing system that receives the rolls either within the air-lock 47, or at the opening to the air-lock chamber 48. This packaging apparatus can be configured to receive the rolls of foil after they have been treated/metallized (e.g. after it has been treated by the physical vapour deposition apparatus) while the air-lock interior is repressurized with the inert gas. It can then seal the rolls of foil a gas tight receiving container whereby the rolls of foil can remain isolated from the air in the ambient environment when the receiving container is removed from the air-lock chamber.

It will also be appreciated by those skilled in the art, that the above air-lock and roll exchange equipment can be more generally applied to the vacuum metallizing equipment, so as to increase the productivity thereof.

While the teachings herein have been described with reference to illustrative embodiments and examples, the description is not intended to be construed in a limiting sense. Thus, various modifications of the illustrative embodiments, as well as other embodiments of the invention, will be apparent to persons skilled in the art upon reference to this description. It is therefore contemplated that the appended claims will cover any such modifications or embodiments.

All publications, patents and patent applications referred to herein are incorporated by reference in their entirety to the same extent as if each individual publication, patent, or patent application was specifically and individually indicated to be incorporated by reference in its entirety.

We claim:

1. An anode assembly for use in a lithium-based battery, the anode assembly comprising:
a) a current collector comprising aluminum and having a first side with a support surface;
b) at least a first protective layer bonded to and covering the support surface, the protective layer comprising a protective metal and being electrically conductive; and
c) at least a first reactive layer comprising lithium metal bonded to the protective layer and being configured to contact an electrolyte when the anode assembly is in use,
wherein the first protective layer is disposed between the support surface and the reactive layer so that electrons can travel from the first reactive layer to the current collector and the first reactive layer is spaced from and at least substantially ionically isolated from the support surface, and whereby diffusion of the reactive layer to the current collector is substantially prevented, by the first protective layer thereby inhibiting reactions between the lithium metal and the current collector.

2. The assembly of claim 1, wherein the current collector comprises a continuous aluminum foil.

3. The assembly of claim 2, wherein the aluminum foil has a thickness of between about 1 and about 100 microns.

4. The assembly of claim 2, wherein the aluminum foil is configured as a continuous web that comprises the support surface and physically supports the first protective layer.

5. The assembly of any one of claims 1 to 4, wherein the protective metal comprises at least one of copper, nickel, silver, stainless steel and steel.

6. The assembly of any one of claims 1 to 5, wherein the first protective layer is deposited onto the support surface via physical vapour deposition and bonds to the support surface in the absence of a separate bonding material.

7. The assembly of any one of claims 1 to 6, wherein the first protective layer has a thickness of between about 1 and about 75,000 Angstroms.

8. The assembly of claim 7, wherein the first protective layer has a thickness of between about 200 and about 7500 Angstroms.

9. The assembly of any one of claims 1 to 8, wherein the first protective layer has an isolation thickness and is shaped so that the first reactive layer is completely ionically isolated from the current collector.

10. The assembly of any one of claims 1 to 9, wherein the protective metal is unreactive with the lithium metal.

11. The assembly of any one of claims 1 to 10, wherein the protective metal covers the entire first side of the current collector.

12. The assembly of any one of claims 1 to 11, wherein the first reactive layer has a thickness of between about 0.001 and about 100 microns.

13. The assembly of claim 12, wherein the first reactive layer has a thickness of between about 0.01 and about 20 microns.

14. The assembly of any one of claims 1 to 13, wherein the first reactive layer is deposited onto the first protective layer via physical vapour deposition and bonds to the first protective layer.

15. The assembly of any one of claims 1 to 14, wherein the anode assembly is free of lithium metal foil.

16. The assembly of any one of claims 1 to 15, wherein the current collector comprises an opposing second side and further comprising a second protective layer bonded to and cover the second side and comprising the protective metal.

17. The assembly of claim 16, wherein a perimeter of the first protective layer is joined to a corresponding perimeter of the second protective layer thereby sealing the current collector with the protective metal.

18. The assembly of claim 17, wherein the first protective layer is joined to a corresponding perimeter of the second protective layer via at least one of physical vapour deposition, application of a polymer film, application of a polymer resin and mechanical crimping of the perimeters.

19. The assembly of claim 16, further comprising a second reactive layer comprising lithium metal bonded to the second protective layer and being configured to contact an electrolyte when the anode assembly is in use.

20. A method of manufacturing an anode assembly for use in an active metal-based battery, the method comprising:
a) providing a current collector comprising metallic substrate and having a first side with a support surface within an interior of a metalizing chamber that is at an operating pressure that is less than about 10⁻² Torr;
b) covering the support surface with at least a first protective layer comprising a protective metal that is electrically conductive and that is deposited on the support surface via a first physical vapour deposition process; and
c) covering the first protective layer with at least a first reactive layer comprising a reactive metal that is deposited on the first protective layer via a second physical vapour deposition process, the first reactive layer being configured to contact an electrolyte when the anode assembly is in use;
whereby the first protective layer is disposed between the support surface and the reactive layer so that electrons can travel from the first reactive layer to the current collector and the first reactive layer is spaced from and at least substantially ionically isolated from the support surface, and whereby diffusion of the reactive layer to the support surface is prevented by the first protective layer thereby inhibiting reactions between the reactive metal and the current collector.

21. The method of claim 20, wherein the metallic substrate is a foil having a thickness of between about 1 and about 100 microns and comprising at least one of copper, aluminium, nickel, stainless steel, steel, an electrically conductive polymer and a polymer.

22. The method of claim 21, wherein the metallic substrate comprises a continuous foil web that is unwound from a first input roll prior to step a) and wound onto a first output roll after step c).

23. The method of claim 22, wherein steps b) and c) are carried out while the web is moving between the first input roll and the first output roll.

24. The method of claim 22, wherein the web is moving at a processing speed of between about 20 and about 1500 m/min.

25. The method of claim 24, wherein step b) comprises providing the protective metal from at least one protective metal vapour source apparatus that is configured to deposit between about 0.001 and about 10 microns of the protective metal on the support surface in a single pass while the web is moving at the processing speed.

26. The method of claim 25, wherein step b) comprise depositing the protective metal onto the support surface until the first protective layer has as thickness of between about 1 and about 75,000 Angstroms.

27. The method of claim 26, wherein step c) comprises providing the reactive metal from at least one reactive metal vapour source apparatus that is spaced downstream from the at least one protective metal vapour source apparatus that is configured to deposit between about 0.001 and about 10 microns of the active metal on the first protective layer in a single pass while the web is moving at the processing speed.

28. The method of claim 27, wherein step c) comprises depositing the active metal onto the first protective layer until first active layer has a thickness of between about 0.001 and about 100 microns.

29. The method of claim 22 or 23, wherein the first input roll is supported by an unwinding apparatus that is disposed within the metalizing chamber.

30. The method of claim 29, wherein the first output roll is supported by a winding apparatus that is disposed within the metalizing chamber at the operating pressure.

31. The method of claim 20 further comprising, prior to step a):
reducing the pressure in the interior of the metalizing chamber from generally atmospheric pressure to the operating pressure; and
introducing the first input roll into the interior of the metalizing chamber via an airlock whereby the first input roll can be conveyed from outside the metalizing chamber to inside the metalizing chamber without increasing a pressure in the interior of the metalizing chamber above I kPa.

32. The method of claim 31, further comprising, after step c), removing the first output roll from the interior of the metalizing chamber via an airlock whereby the first output roll can be conveyed from inside the metalizing chamber to outside the metalizing without increasing a pressure within the interior of the metalizing chamber above I kPa.

33. The method of claim 32, further comprising sealing the first output roll within an air tight receiving chamber having an interior that is substantially free of oxygen prior to removing the first output roll from the airlock.

34. The method of claim 31, further comprising, after depleting the first input roll introducing a second input roll into the interior of the metalizing chamber via an airlock and without increasing a pressure in the interior of the metalizing chamber above I kPa, and repeating steps a) to c) with a metallic substrate unwound from the second input roll.

35. The method of claim 20, wherein the reactive metal comprises at least one of lithium, potassium, rubidium, cesium, calcium, magnesium and aluminum.

36. The method of claim 35, wherein the reactive metal is lithium.

37. The method of claim 20, wherein the interior of the metalizing chamber is substantially free of oxygen during steps a)-c).

38. The method of claim 20, further comprising covering an opposing a second side of the current collector with a second protective layer comprising the protective metal via a third physical vapour deposition process.

39. The method of claim 38, further comprising sealing a perimeter of the first protective layer to a perimeter of the second protective layer to seal the current collector.

40. The method of claim 39, wherein sealing the perimeter of the first protective layer to the perimeter of the second protective layer comprises mechanically crimping the perimeters together.

41. The method of claim 38, further comprising covering the second protective layer with a second reactive layer comprising the reactive metal via a fourth physical vapour deposition process.

42. The method of claim 20, wherein the operating pressure is between about 10⁻² and 10⁻⁶ Torr.

43. A lithium-based battery comprising:
a) a cathode assembly comprising a cathode current collector and a cathode reactive surface
b) a lithium anode assembly comprising:
i. an anode current collector comprising aluminum and having a first side with a support surface;
ii. at least a first protective layer bonded to and covering the support surface, the protective layer comprising a protective metal and being electronically conductive; and
iii. at least a first reactive layer comprising lithium metal bonded to the protective layer and being configured to contact an electrolyte when the anode assembly is in use,
c) an electrolyte disposed between and contacting the cathode reactive surface and the anode reactive layer;
wherein the first protective layer is disposed between the support surface and the reactive layer so that electrons can travel through the first reactive layer and first protective layer from the electrolyte to the anode current collector, and the first reactive layer is spaced from and at least substantially ionically isolated from the support surface, whereby diffusion of the reactive layer to the current collector is substantially prevented by the first protective layer thereby inhibiting reactions between the lithium metal and the current collector.

44. The battery of claim 43, wherein the first protective layer at least substantially ionically isolates the support surface from the electrolyte.

45. The battery of claim 43, wherein the electrolyte comprises a solid electrolyte material that directly contacts that first reactive layer and does not directly contact the anode current collector.

46. The battery of claim 43, wherein the anode collector is encased by the protective metal and is physically isolated from the electrolyte.

47. The assembly of claim 43, wherein the current collector comprises a continuous aluminum foil.

48. The assembly of claim 47, wherein the aluminum foil has a thickness of between about 1 and about 100 microns.

49. The assembly of claim 47, wherein the aluminum foil is configured as a continuous web that comprises the support surface and physically supports the first protective layer.

50. The assembly of any one of claims 43 to 49, wherein the protective metal comprises at least one of copper, nickel, silver, stainless steel and steel.

51. The assembly of claim 50, wherein the first protective layer is deposited onto the support surface via physical vapour deposition and bonds to the support surface.

52. The assembly of claim 43, wherein the first protective layer has a thickness of between about 1 and about 75,000 Angstroms.

53. The assembly of claim 52, wherein the first protective layer has a thickness of between about 200 and about 7500 Angstroms.

54. The assembly of claim 43, wherein the first protective layer has an isolation thickness and is shaped so that the first reactive layer is completely ionically isolated from the current collector.

55. The assembly of claim 43, wherein the protective metal is unreactive with the lithium metal.

56. The assembly of claim 43, wherein the protective metal covers the entire first side of the current collector.

57. The assembly of claim 43, wherein the first reactive layer has a thickness of between about 0.001 and about 100 microns.

58. The assembly of claim 57, wherein the first reactive layer has a thickness of between about 0.01 and about 20 microns.

59. The assembly of claim 43, wherein the first reactive layer is deposited onto the first protective layer via physical vapour deposition and bonds to the first protective layer.

60. The assembly of claim 43, wherein the anode assembly is free of lithium metal foil.

61. The assembly of claim 43, wherein the current collector comprises an opposing second side and further comprising a second protective layer bonded to and cover the second side and comprising the protective metal.

62. The assembly of claim 61, wherein a perimeter of the first protective layer is joined to a corresponding perimeter of the second protective layer thereby sealing the current collector with the protective metal.

63. The assembly of claim 61, wherein the first protective layer is joined to a corresponding perimeter of the second protective layer via at least one of physical vapour deposition, application of a polymer film, application of a polymer resin and mechanical crimping of the perimeters.

64. The assembly of claim 61, further comprising a second reactive layer comprising lithium metal bonded to the second protective layer and being configured to contact an electrolyte when the anode assembly is in use.

65. A roll-to-roll metallizing apparatus, the apparatus comprising:
a) a metallizing chamber having an interior that is configurable at an operating pressure that is less than about 0.001 kPa during a first vacuum cycle;
b) a roll-to-roll winding assembly within the metallizing chamber and comprising a first spindle supporting a first roll of foil for unwinding, a second spindle onto which foil can be wound and a first foil web travelling therebetween;
c) a physical vapour deposition apparatus within the metallizing chamber and configured to, during the first vacuum cycle, treat the first roll of foil by independently depositing i) a layer of a protective metal onto the first foil web travelling between the first spindle and second spindle and ii) a layer of a reactive material onto the layer of protective material;
d) an air-lock chamber having an interior that is configurable at about the operating pressure during the first vacuum cycle and configured to simultaneously accommodate at least the first roll of foil and the second roll of foil;
e) a chamber door that separates the interior of the metallizing chamber and the interior of the air-lock chamber, and when the air-lock chamber is at a transfer pressure that is less than atmospheric pressure is movable between:
i. a closed configuration in which the interior of the metallizing chamber is sealed and isolated from the interior of the air-lock chamber; and
ii. an open configuration in which the interior of the metallizing chamber is in communication with the interior of the air-lock chamber whereby the second roll of foil can be moved from the air-lock chamber into the metallizing chamber while maintaining the interior of the metallizing chamber at the transfer pressure;
whereby after the first roll of foil is removed from the metallizing chamber the second roll of foil is mountable on the first spindle so that a second foil web extends between the first spindle and the second spindle and the second foil web is treatable using the physical vapour deposition apparatus during the first vacuum cycle to deposit i) a second layer of a protective metal onto the second foil web travelling between the first spindle and second spindle and ii) a second layer of a reactive material onto the second layer of protective material.

66. The apparatus of claim 65, wherein when the chamber door is open the first roll of foil is movable from the metallizing chamber into the air-lock chamber.

67. The apparatus of claim 66, wherein the transfer pressure is less than about 0.01 kPa.

68. The apparatus of claim 67, wherein the transfer pressure is substantially the same as the operating pressure.

69. The apparatus of claim 65, wherein the physical vapour deposition apparatus further comprises: a first applicator configured to deposit the layer of a protective metal on the first foil web in a first deposition zone, and, a second applicator that is configured to deposit the layer of a reactive metal on top of the layer of protective metal.

70. The apparatus of claim 66, wherein the first foil web travels in a travel direction when the first foil web is transferred from the first spindle to the second spindle, and wherein the second applicator is spaced from the first applicator in the travel direction.

71. The apparatus of claim 70, wherein the layer of reactive metal is deposited in a second deposition zone that is spaced from the first deposition zone in the travel direction.

72. The apparatus of claim 71, wherein the physical vapour deposition apparatus is configured to apply the layer of protective metal in a single pass of the first foil web through the first deposition zone.

73. The apparatus of claim 71 or 72, wherein the physical vapour deposition apparatus is configured to apply the layer of reactive metal in a single pass of the first foil web through the second deposition zone.

74. The apparatus of claim 65, wherein the air-lock chamber further comprises an air-lock door that is movable independently of the chamber door between:
a) a closed configuration in which the interior of the air-lock chamber is sealed and isolated from the ambient environment; and
b) an open configuration in which the interior of the air-lock chamber is in communication with the ambient environment.
whereby when the chamber door is closed and the air-lock door is open the interior of the air-lock can be accessed from the ambient environment to while the metallizing chamber remains at the operating pressure.

75. The apparatus of claim 74, further comprising a roll magazine apparatus disposed within the air-lock chamber and configured to receive the first roll of foil roll-to-roll winding assembly, simultaneously hold the first roll of foil and the second roll of foil, and then to transfer the second roll of foil from roll magazine apparatus to the roll-to-roll winding assembly while the metallizing chamber is maintained at the transfer pressure.

76. The apparatus of claim 74, further comprising an inert repressurization system that is configured to repressurize the interior of the air lock chamber when the chamber door and air-lock door are closed to about atmospheric pressure using an inert gas that is inert relative to the reactive material.

77. The apparatus of claim 76, further comprising a packaging apparatus within the air-lock chamber, the packaging apparatus configured to receive the first roll of foil after it has been treated by the physical vapour deposition apparatus and, while the air-lock interior is repressurized with the inert gas, to seal the first roll of foil in a gas tight receiving container whereby the first roll of foil remains isolated from the air in the ambient environment when the receiving container is removed from the air-lock chamber.
